(19) United States
(12) Patent Application Publication
(10) Pub. No.: US 2026/0096209 A1
(43) Pub. Date: Apr. 2, 2026

(54) INTEGRATED CIRCUIT HAVING FILLER CELL AND METHOD OF FABRICATING THE SAME

(71) Applicant: TAIWAN SEMICONDUCTOR MANUFACTURING COMPANY, LTD., Hsinchu (TW)

(72) Inventors: Chun-Yen LIN, Hsinchu (TW); Wei-Cheng TZENG, Hsinchu (TW); Shih-Wei PENG, Hsinchu (TW); Wei-Cheng LIN, Hsinchu (TW); Jiann-Tyng TZENG, Hsinchu (TW)

(21) Appl. No.: 19/077,629

(22) Filed: Mar. 12, 2025

Related U.S. Application Data
(60) Provisional application No. 63/701,226, filed on Sep. 30, 2024.

(51) Int. Cl. H10D 84/90; H10D 89/10

(52) U.S. Cl. CPC H10D 84/981; H10D 84/953; H10D 89/10

(57) ABSTRACT

An integrated circuit device includes a first stack of active-region structures extending in a first direction and including a lower and upper active-region structures stacked with each other; a front-side power rail extending in an upper conductive layer above the lower and upper active-region structures; a back-side power rail extending in a lower conductive layer below the lower and upper active-region structures; an array of vertical power lines each extending in a second direction in a conductive layer different from the upper conductive layer and the lower conductive layer, the second direction being perpendicular to the first direction; and a filler cell having therein a segment of the first stack of active-region structures and having therein a power via-connector which extends in the third direction and conductively connects the front-side power rail with the back-side power rail, and wherein the filler cell is between two of the vertical power lines.

### PRIORITY CLAIM

The present application claims the priority of U.S. Provisional Application No. 63/701,226, filed Sep. 30, 2024, which is incorporated herein by reference in its entirety.

### BACKGROUND

Integrated circuit designs are increasingly complex, and corresponding increases in the area density of circuit structures are desired. One approach to increasing area density of integrated circuits is to implement three-dimensional device structures, with power and/or signal structures that are on top and bottom sides of the three-dimensional device structures.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic layout diagram of an integrated circuit, in accordance with some embodiments.

FIG. 2A is a layout diagram of a logic circuit cell including an inverter circuit, in accordance with some embodiments.

FIGS. 2B-2D are cross-sectional views of a logic circuit cell including an inverter circuit, in accordance with some embodiments.

FIG. 3A is a layout diagram of a logic circuit cell, in accordance with some embodiments.

FIG. 3B is across-sectional view of a logic circuit cell, in accordance with some embodiments.

FIG. 4A is a layout diagram of a logic circuit cell, in accordance with some embodiments.

FIG. 4B is across-sectional view of a logic circuit cell, in accordance with some embodiments.

FIG. 5A is a layout diagram of a filler cell, in accordance with some embodiments.

FIGS. 5B-5D are cross-sectional views of a filler cell, in accordance with some embodiments.

FIG. 6A is a layout diagram of a filler cell, in accordance with some embodiments.

FIGS. 6B-6D are cross-sectional views of a filler cell, in accordance with some embodiments.

FIG. 7A is a layout diagram of a filler cell, in accordance with some embodiments.

FIGS. 7B-7D are cross-sectional views of a filler cell, in accordance with some embodiments.

FIGS. 8A-8B are cross-sectional views of the integrated circuit, in accordance with some embodiments.

FIGS. 9A-9D are stages in forming a layout, in accordance with some embodiments.

FIG. 10 is a flowchart of a method of forming a layout, in accordance with some embodiments.

FIG. 11 is a flowchart of a method of fabricating an integrated circuit having a filler cell, in accordance with some embodiments.

FIG. 12 is a flowchart of a method of manufacturing an IC device according to some embodiments.

FIG. 13 is a block diagram of an IC device design system according to some embodiments.

FIG. 14 is a block diagram of an IC manufacturing system, and an IC manufacturing flow associated therewith, according to some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In an integrated circuit that has conductors, e.g., power conductors, on top and bottom sides of three-dimensional device structures, it is desirable in some instances to provide conductors that pass through the three-dimensional structures to connect a top conductor with a bottom conductor. For example, in some instances a front-side power rail and a back-side power rail are connected to distribute a common power voltage to the front and back sides of the integrated circuit. Such connections occupy areas of the integrated circuit that could otherwise be used for functional circuits, e.g., logic circuits (or logic circuit cells) and the like. Also, although modern integrated circuit designs are extremely dense, i.e., are highly efficient at using substrate area (e.g., wafer or die area) for functional circuits, device area utilization for functional circuits can be less than a maximum available substrate area. Thus, a substrate can have areas that are not used for functional circuits (e.g., logic circuit cells).

An integrated circuit according to some embodiments includes one or more filler cells that include conductors that connect front-side power rails with back-side power rails. In some embodiments, the filler cells are implemented in areas that are not used for functional circuits, e.g., in spaces in rows of a layout that are not being used for logic circuit cells. In some embodiments, the sizes of the filler cells are varied in accordance with space left in rows after placement of logic circuit cells. The locations of the filler cells, the number of the filler cells, and/or the sizing of the filler cells are adaptable to unutilized layout area, e.g., area remaining after placement of logic circuit cells, to provide front-back power connections without incurring an area penalty or constraining the placement of the logic circuit cells. In some embodiments, the filler cells provide sufficient front-back power connections to allow other front-back power structures, e.g., regularly-arranged structures that are placed before the logic circuit cells, to be reduced in number and/or placed at a larger pitch, thus increasing available area for logic circuit cell placement.

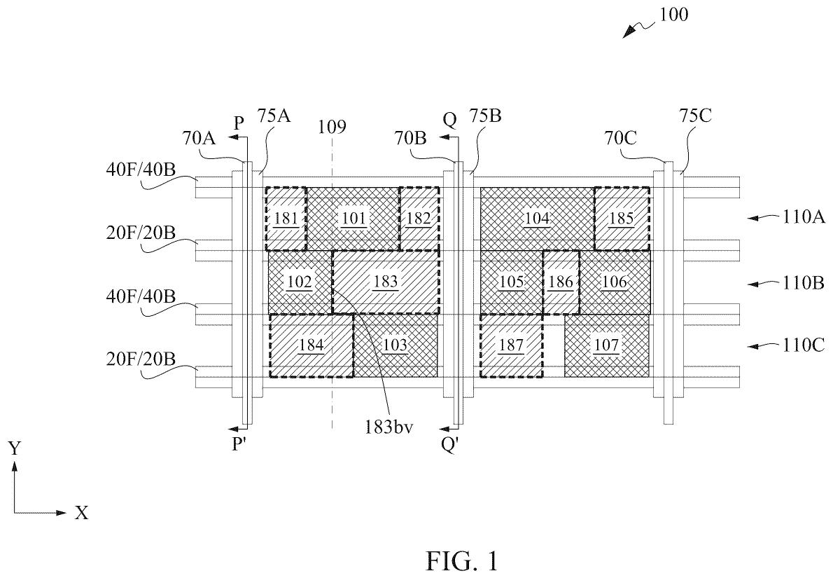

FIG. 1 is a schematic layout diagram of an integrated circuit 100, in accordance with some embodiments.

The integrated circuit 100 includes multiple rows of cells. In FIG. 1, by way of example, three rows of cells (i.e., first, second, and third rows 110A, 110B, and 110C), each extending in the X-direction, are shown explicitly. The second row 110B is between the first row 110A and the second row 110C relative to the Y-direction. Other rows in in the integrated circuit 100, e.g., in the area adjacent to the first row 110A and/or in the area adjacent to the third row 110C, are not explicitly shown in FIG. 1. In some embodiments, each of first, second, and third rows 110A, 110B, and 110C includes one or more active regions extending in the X-direction on a substrate. In some embodiments, the active regions include nanosheets, e.g., of silicon or another semiconductor. In some embodiments, the active regions include nanowires. In some embodiments, each of rows 110A-110C includes a set of a first-type active-region structure 80F and a second-type active-region structure 80B in a stack along the Z-direction (perpendicular to the substrate). In some embodiments, one or both of the first-and second-type active-region structures 80F and 80B includes nanosheets, nanowires, or the like.

The integrated circuit 100 includes multiple power rails 20F/20B and 40F/40B extending in the X-direction. In FIG. 1, a first front-side power rail 20F overlaps a first back-side power rail 20B, and a second front-side power rail 40F overlaps a second back-side power rail 40B. The first and second front-side power rails 20F and 40F are in an upper conductive layer. The first and second back-side power rails 20B and 40B are in a lower conductive layer. In some embodiments, the first and second back-side power rails 20B and 40B are on a same side of a substrate as the first and second front-side power rails 20F and 40F, e.g., by forming the first and second back-side power rails 20B and 40B as buried power rails prior to forming the active-region structures, contact structures (MD structures), gate structures, and the like over the first and second back-side power rails 20B and 40B as buried power rails. In other embodiments, the first and second back-side power rails 20B and 40B are on an opposite side of a substrate from the first and second front-side power rails 20F and 40F, e.g., by forming the first and second back-side power rails 20B and 40B on an opposite side of the substrate from the active-region structures, contact structures (MD structures), gate structures, and the like.

The power rails 20F/20B are interlaced with the power rails 40F/40B relative to the Y-direction. Each of the power rails 20F/20B and the power rails 40F/40B overlaps with a boundary extending in the X-direction between two rows of cells. In some embodiments, each of the power rails 20F/20B is configured to be maintained at a first supply voltage (e.g., one of VDD or VSS), and each of the power rails 40F/40B is configured to be maintained at a second supply voltage different from the first supply voltage (e.g., the other of VDD or VSS). In other embodiments, two or more immediately-adjacent rows of power rails are configured to be maintained at a same power supply voltage, i.e., the power supply voltages do not alternate by each row but are instead arranged with a different pattern. Further, although FIG. 1 shows pairs of first front-and back-side power rails 20F/20B and 40F/40B, in some embodiments, one of the first front-or back-side power rails 20F or 20B is omitted from one or more rows, and/or one of the second front-or back-side power rails 40F or 40B is omitted from one or more rows.

In the integrated circuit 100, logic circuit cells 101 and 104 and filler cells 181-182 and 185 are positioned in the first row 110A. Logic circuit cells 102 and 105-106 and filler cells 183 and 186 are positioned in the second row 110B. Logic circuit cells 103 and 107 and filler cells 184 and 187 are positioned in the third row 110C. In other embodiments, more or fewer logic circuit cells and/or more of fewer filler cells are in the first, second, and/or third rows 110A, 110B, and/or 110C. Examples of logic circuit cells include inverter gate cells, NAND gate cells, NOR gate cells, AND-OR-invert (AOI) logic gate cells, flip-flop circuit cells, and the like.

A filler cell includes a power via-connector which conductively connects the front-side power rail with the back-side power rail. The power via-connector extends in the Z-direction, i.e., a direction perpendicular to the surface of the substrate. In some embodiments, a filler cell connects the front-side power rail with the back-side power rail using conductors arranged between a first conductor in a conductive M0 layer and a second conductor in a conductive BM0 layer. In some embodiments, a filler cell connects the front-side power rail with the back-side power rail using conductors arranged between a first conductor in a conductive M0 layer and a second conductor in a conductive BM0 layer, and does not use conductors above the M0 layer or below the BM0 layer to connect the front-side power rail with the back-side power rail.

Each of the filler cells does not perform logic operations. In some embodiments, a filler cell does not have any dynamic transistor, whereas a logic circuit cell does have at least one dynamic transistor. Here, a dynamic transistor is a transistor which has a channel state configured to change with time. That is, during the circuit operation in the logic circuit cells, a dynamic transistor is sometimes at a conducting state and sometimes at a non-conducting state. In some embodiments, a filler cell does not have any transistor implemented therein. In some embodiments, a filler cell has a transistor implemented therein, but the transistor has a channel state configured to remain unchanged with time (such a transistor may be referred to as a non-dynamic transistor). In some embodiments, a filler cell has a transistor implemented therein while having source and drain tied to a same constant voltage or power source, having a gate tied to a constant voltage or power source, or the like (such a transistor may also be referred to as a non-dynamic transistor). In some embodiments, a filler cell has a transistor that has one or more of source, drain, and gate that is not coupled to power or signal, e.g., to be in a floating state (such a transistor may also be referred to as a non-dynamic transistor). In some embodiments, one or more of the filler cells have dynamic transistors and/or non-dynamic transistors that are logically decoupled from the logic circuit cells.

Aspects of the filler cells 181-187 are described in further detail below with reference to the filler cell 181 as an example.

In FIG. 1, the integrated circuit 100 includes an array of vertical power lines extending in the Y-direction. First, second, and third vertical power lines 70A, 70B, and 70C are shown in the figure as examples. Each vertical power line in the array of vertical power lines extends in the Y-direction in a conductive layer which is different from the upper conductive layer (in which the first and second front-side power rails 20F and 40F are implemented) and the lower conductive layer (in which first and second back-side power rails 20B and 40B are implemented). In some embodiments, the first vertical power line 70A is coupled to a first supply voltage (e.g., one of VDD or VSS), the second vertical power line 70B is coupled a second supply voltage (e.g., the other of VDD or VSS), and the third vertical power line is coupled to the first supply voltage.

The vertical power lines correspond to, e.g., vertically overlap, power tap cells that connect power between the front and back sides of the integrated circuit 100. The first vertical power line 70A corresponds to a first power tap structure region 75A. The second vertical power line 70B corresponds to a second power tap structure region 75B. The third vertical power line 70C corresponds to a third power tap structure region 75C. In some embodiments, the vertical power lines and corresponding power tap structure regions alternate in the X-direction, such that the third vertical power line 70C and corresponding third power tap structure region 75C are the same as the first vertical power line 70A and the first power tap structure region 75A. In some embodiments, none of the vertical power lines pass across or vertically overlap a filler cell.

In some embodiments, the first row 110A includes a first stack of the first-and second-type active-region structures 80F and 80B (which extend along the row direction (X-direction) in the first row 110A), the second row 110B includes a second stack of the first-and second-type active-region structures 80F and 80B (which extend along the row direction (X-direction) in the second row 110B), the third row 110C includes a third stack of the first-and second-type active-region structures 80F and 80B (which extend along the row direction (X-direction) in the third row), and each of the first, second, and third vertical power lines 70A, 70B, and 70C extends across each of the first stack, the second stack, and the third stack of first-and second-type active-region structures 80F and 80B. In some embodiments, for a filler cell located in the second row 110B, none of the first stack of active-region structures and none of the third stack of active-region structures passes through that filler cell.

In FIG. 1, the first, second, and third power tap structure regions 75A, 75B, and 75C are arranged at a regular pitch in the X-direction. In some embodiments, the first, second, and third power tap structure regions 75A, 75B, and 75C are arranged at an integer multiple of a gate pitch or contact poly pitch (CPP). In some embodiments, the power tap structure regions 75A, 75B, and 75C are included in one or more power tap cells aligned in the Y-direction. In some embodiments, each of the first, second, and third power tap structure regions 75A, 75B, and 75C corresponds to a multi-row-height power tap cell. In other embodiments, each of the first, second, and third power tap structure regions 75A, 75B, and 75C corresponds to a plurality of power tap cells aligned in the Y-direction. In FIG. 1, the first, second, and third power tap structure regions 75A, 75B, and 75C each extend in the Y-direction beyond the corresponding row boundaries (i.e., beyond the upper boundary of first row 110A and below the lower boundary of third row 110C) to indicate that the first, second, and third power tap structure regions 75A, 75B, and 75C continue in the Y-direction both above first row 110A and below third row 110C. In other embodiments (not shown in FIG. 1), the power tap structure regions have tops and/or bottoms aligned with a row boundary. In some embodiments (not shown in FIG. 1), the power tap structure regions have a height in the row-height direction (Y-direction) that is equal to one row or less than one row.

In some embodiments, power tap cells corresponding to the first, second, and third power tap structure regions 75A, 75B, and 75C are placed in a layout for the integrated circuit 100 prior to placing the logic circuit cells 101-107 and prior to placing the filler cells 181-187. In some embodiments, cells corresponding to the first, second, and third power tap structure regions 75A, 75B, and 75C are placed in a layout for the integrated circuit 100 prior to placing the logic circuit cells 101-107, and the logic circuit cells 101-107 are placed in the layout prior to placing the filler cells 181-187.

In some embodiments, the filler cells are placed in a layout for the integrated circuit 100 after placing the logic circuit cells. In some embodiments, the filler cells 181-187 are sized to have cell widths (in the X-direction or row-extending direction) that are based on spaces that remain in the rows 110A-110C after first placing the cells corresponding to the first, second, and third power tap structure regions 75A, 75B, and 75C and the logic circuit cells 101-107.

As discussed above, a filler cell includes a power via-connector which conductively connects a front-side power rail with a back-side power rail. In some embodiments, wider filler cells (i.e., wider in the row-extending direction, X) include a wider power via-connector (i.e., wider in the row-extending direction, X) than narrower filler cells. In other embodiments, wider filler cells include a greater number of power-via connectors than narrower filler cells. Including the filler cells in the layout provides additional electrical connections between front-side and back-side power rails, helping to reduce IR drop between front-side and back-side power rails. In some embodiments, the filler cells improve area utilization of a layout. For example, if logic circuit cells occupy eighty percent of available cell area, the filler cells can be placed in some or all of the remaining twenty percent of available cell area to provide additional electrical connections between front-side and back-side power rails. In some embodiments, the enhanced electrical connectivity between front-side and back-side conductors provided by the filler cells enables a reduction in number of, and/or increased spacing between, other front-back connecting regions such as power tap cells. In some embodiments, area utilization by logic circuit cells is increased by placing one or more filler cells while increasing an X-direction pitch of power tap cells.

In some embodiments, one or more vertical boundaries (i.e., Y-direction boundaries) of the filler cells are offset in the row-extending direction (i.e., offset in the X-direction) relative to one or more vertical boundaries of the logic circuit cells. In FIG. 1, an example of this offset is indicated with reference to a reference line 109. The reference line 109 extends in the vertical direction (Y-direction) parallel to the vertical cell boundaries of the filler cells and the logic circuit cells. Filler cell 183 in row 110B has a vertical cell boundary 183bv extending in the vertical direction along the reference line 109. The vertical cell boundary 183bv of the filler cell 183 is between the two vertical cell boundaries of logic circuit cell 101, which is adjacent to the filler cell 183 in the first row 110A.

In the example just described, the filler cell 183 is in a row (second row 110B) that is adjacent to the row (first row 110A) having the logic circuit cell 101. In some embodiments, the filler cell 183 encompasses segments of a first set of the first-and second-type active-region structures 80F and 80B (in the second row 110B), and the logic circuit cell 101 encompasses segments of a second set of the first-and second-type active-region structures 80F and 80B (in the first row 110A).

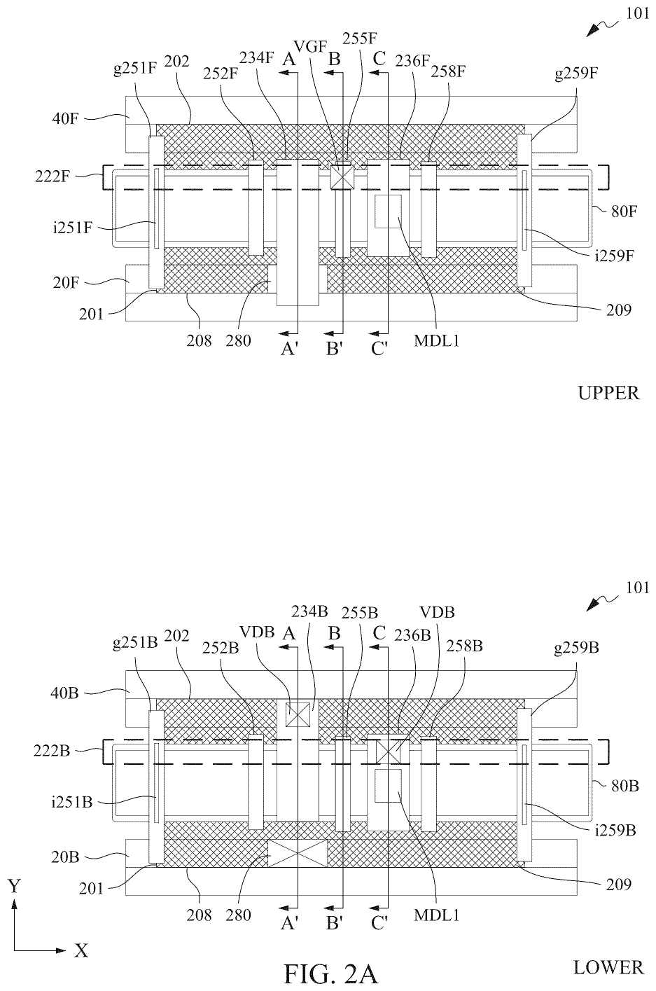

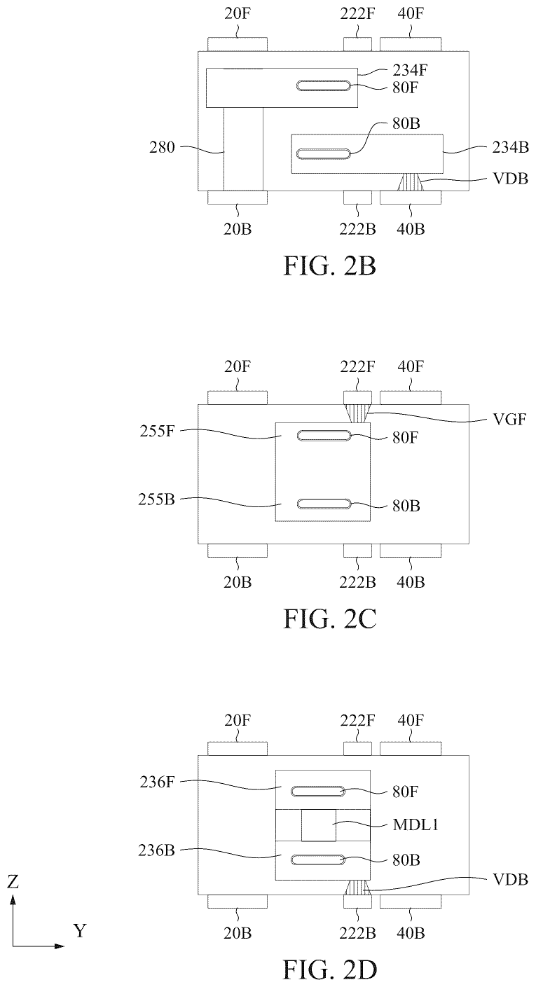

FIG. 2A is a layout diagram of a logic circuit cell 101 including an inverter circuit, in accordance with some embodiments. In some embodiments, the logic circuit cell 101 of FIG. 2A corresponds to the logic circuit cell 101 of FIG. 1. In some embodiments, the logic circuit cell 101 of FIG. 2A corresponds to one or more of the logic circuit cells 102-107 of FIG. 1. The inverter circuit is merely an example of a logic circuit, and the logic circuit cell 101 is implemented with other logic circuits in other embodiments.

FIGS. 2B-2D are cross-sectional views of the logic circuit cell 101 including an inverter circuit in FIG. 2A, in accordance with some embodiments. Specifically, cross-sectional views of the logic circuit cell 101 in cutting planes as specified by the lines A-A′, B-B′, and C-C′ in FIG. 2A are correspondingly depicted in FIG. 2B, FIG. 2C, and FIG. 2D. Upper portions of lines A-A′, B-B′, and C-C′ in FIG. 2A (i.e., A, B, and C) correspond to right sides in FIGS. 2B-2D.

The layout diagram in FIG. 2A includes an upper portion (labeled ‘UPPER’) and a lower portion (labeled ‘LOWER’). The logic circuit cell 101 includes first and second horizontal cell boundaries 202 and 208 that extend in the X-direction while being spaced apart in the Y-direction. The logic circuit cell 101 also includes first and second vertical cell boundaries 201 and 209 that extend in the Y-direction while being spaced apart in the X-direction.

The upper portion of the layout diagram includes layout patterns for specifying a first-type active-region structure 80F, gate-conductors 252F, 255F, and 258F, terminal-conductors 234F and 236F, an upper-layer conducting line 222F, a first front-side power rail 20F, a second front-side power rail 40F, a terminal-inter-connector MDL1, a dummy gate-conductor g251F at the first vertical cell boundary 201, a dummy gate-conductor g259F at the second vertical cell boundary 209, and a gate via-connector VGF. Although FIG. 2A shows one upper-layer conducting line 222F extending in the X-direction in the upper layer in the logic circuit cell 101, in various embodiments two or more conducting lines extend in parallel in the upper layer in the logic circuit cell 101 while being spaced apart from each other in the Y-direction, e.g., at a regular pitch. In FIG. 2A, the upper-layer conducting line 222F is in a same conductive layer as the first and second front-side power rails 20F and 40F, e.g., in a first metallization layer M0.

The lower portion of the layout diagram includes layout patterns for specifying a second-type active-region structure 80B, gate-conductors 252B, 255B, and 258B, terminal-conductors 234B and 236B, a lower-layer conducting line 222B, a first back-side power rail 20B, a second back-side power rail 40B, the terminal-inter-connector MDL1, a dummy gate-conductor g251B at the first vertical cell boundary 201, and a dummy gate-conductor g259B at the second vertical cell boundary 209, and various via-connectors VDB. Although FIG. 2A shows one lower-layer conducting line 222B extending in the X-direction in lower layer in the logic circuit cell 101, in various embodiments two or more conducting lines extend in parallel in the lower layer the logic circuit cell 101 while being spaced apart from each other in the Y-direction, e.g., at a regular pitch. Although FIG. 2A shows one pair of conducting lines 222F/222B, it will be understood that in some embodiments the pair of conducting lines 222F/222B is just one of several parallelly-positioned routing lines in the upper conducing layer and the lower conducting layer. The number of upper-layer conducting lines 222F is the same as the number of lower-layer conducting lines 222B is the same in some embodiments and is different in other embodiments. In FIG. 2A, the lower-layer conducting line 222B is in a same conductive layer as the first and second back-side power rails 20B and 40B, e.g., in a first back-side metallization layer BM0.

In the layout diagram of FIG. 2A, each of the first-type active-region structure 80F and the second-type active-region structure 80B extends in the X-direction. Various gate-conductors (e.g., 252F, 255F, 258F, 252B, 255B, and 258B) and various terminal-conductors (e.g., 234F, 236F, 234B and 236B) extend in the Y-direction. In some embodiments, the first-type active-region structure 80F is stacked with the second-type active-region structure 80B at a front side of a substrate and shifted from the second-type active-region structure along the Z-direction, i.e., shifted normal to the substrate. The stacking of the first-type active-region structure 80F and the second-type active-region structure 80B along the Z-direction is also depicted in the cross-sectional views of FIGS. 2B-2D. In FIG. 2A and FIGS. 2B-2D, the X-direction, the Y-direction, and the Z-direction are mutually orthogonal to each other and form an orthogonal coordinate frame.

In the layout diagram of FIG. 2A, the gate-conductor 255F extending in the Y-direction intersects the first-type active-region structure 80F at a channel region of a first-type transistor, and the gate-conductor 255B extending in the Y-direction intersects the second-type active-region structure 80B at a channel region of a second-type transistor. Each of the terminal-conductors 234F and 236F, extending in the Y-direction, intersects the first-type active-region structure 80F at one of the terminal regions of the first-type transistor. Each of the terminal-conductors 234B and 236B, extending in the Y-direction, intersects the second-type active-region structure 80B at one of the terminal regions of the second-type transistor. A terminal region of a transistor is either a source region or a drain region of the transistor.

In some embodiments, the first-type transistor formed with the first-type active-region structure 80F is a PMOS transistor, and the second-type transistor formed with the second-type active-region structure 80B is an NMOS transistor. In other embodiments, the first-type transistor formed with the first-type active-region structure 80F is an NMOS transistor, and the second-type transistor formed with the second-type active-region structure 80B is a PMOS transistor. A CFET device is formed with a first-type transistor stacked with a second-type transistor relative to the Z-direction.

In some embodiments, each of the first-type active-region structure 80F and the second-type active-region structure 80B includes one or more nano-sheets, in which case each of the PMOS transistor and the NMOS transistor in FIG. 2A may be referred to as a nano-sheet transistor. In some embodiments, each of the first-type active-region structure 80F and the second-type active-region structure 80B includes one or more nano-wires, in which case each of the PMOS transistor and the NMOS transistor in FIG. 2A may be referred to as a nano-wire transistor.

In the layout diagram of FIG. 2A, the first and second front-side power rails 20F, 40F extending in the X-direction are in an upper conductor layer, and the back-side power rails 20B, 40B extending in the X-direction are in a lower conductor layer. As shown in FIGS. 2B-2D, the upper conductor layer is above both the first-type active-region structure 80F and the second-type active-region structure 80B, while the lower conductor layer is below both the first-type active-region structure 80F and the second-type active-region structure 80B. In addition, upper-layer conducting line 222F extending in the X-direction is implemented in the upper conductor layer, and lower-layer conducting line 222B extending in the X-direction is implemented in the lower conductor layer.

In the example shown in FIG. 2A and FIGS. 2B-2D, the first-type transistor and the second-type transistor are coupled with each other to form an inverter circuit which is configured to receive voltage supplies from the power rails 20F/20B and the power rails 40F/40B.

In FIG. 2A and FIG. 2D, the terminal-conductor 236F (as the drain terminal of the first-type transistor) and the terminal-conductor 236B (as the drain terminal of the second-type transistor) are conductively connected together through the terminal-inter-connector MDLI. The terminal-conductor 236F and the terminal-conductor 236B form an output node of the inverter circuit. The terminal-conductor 236B is connected to the lower-layer conducting line 222B thorough a via-connector VDB, whereby the lower-layer conducting line 222B is configured to receive an output signal of the inverter circuit from the terminal-conductor 236B.

In FIG. 2A and FIG. 2C, the gate-conductor 255F and the gate-conductor 255B are joined together and form an input node of the inverter circuit. The gate-conductor 255F is connected to the upper-layer conducting line 222F through the gate via-connector VGF, whereby the gate-conductor 255F (as of the input node of the inverter circuit) is configured to receive an input signal from the upper-layer conducting line 222F. In other embodiments (not shown in FIGS. 2A-2B), the gate-conductor 255B is connected to the lower-layer conducting line 222B through a via-connector, whereby the gate-conductor 255B (as of the input node of the inverter circuit) is configured to receive an input signal from the lower-layer conducting line 222B.

In FIG. 2A and FIG. 2B, the terminal-conductor 234F, which functions as the source terminal of the first-type transistor, is conductively connected to the first back-side power rail 20B through a via-connector 280. The terminal-conductor 234B, which functions as the source terminal of the second-type transistor, is conductively connected to the second back-side power rail 40B through a lower via-connector VDB. In some embodiments, the first-type transistor is a PMOS transistor and the second-type transistor is an NMOS transistor, and the first back-side power rail 20B is configured to provide a first power supply voltage VDD while the second back-side power rail 40B is configured to provide a second power supply voltage VSS. In some embodiments, the first-type transistor is an NMOS transistor and the second-type transistor is a PMOS transistor, and the first back-side power rail 20B is configured to provide a second power supply voltage VSS while the second back-side power rail 40B is configured to provide a first power supply voltage VDD.

In FIG. 2A, the first-type transistor formed with the gate-conductor 255F and the second-type transistor formed with the gate-conductor 255B are stacked as a CFET device. The inverter circuit in the logic circuit cell 101 is implemented with a first CFET device formed with the gate-conductors 255F and 255B. Additional circuits in the logic circuit cell 101 are implemented with other CFET devices, such as a second CFET device formed with the gate-conductors 252F and 252B and a third CFET device formed with the gate-conductors 258F and 258B. Not shown in FIG. 2A are layout patterns for specifying the terminal-conductors of the second CFET device and the third CFET device and the layout patterns for specifying additional elements (such as via-connectors and terminal-inter-connectors) in the additional circuits.

The logic circuit cell 101 is bounded by the dummy gate-conductors g251F and g251B at one side (at first vertical cell boundary 201) and the dummy gate-conductors g259F and g259B at the opposite side (second vertical cell boundary 209). The first vertical cell boundary 201 of the logic circuit cell 101 is aligned with the dummy gate-conductors g251F and g251B. The second vertical cell boundary 209 of the logic circuit cell 101 is aligned with the dummy gate-conductors g259F and g259B. In some embodiments, the cell width of the logic circuit cell 101 measured along the X-direction corresponds to the pitch distance between the dummy gate-conductors g251F and g259F or by the pitch distance between the dummy gate-conductors g251B and g259B.

The dummy gate-conductor g251F corresponds to a boundary isolation region i251F. The dummy gate-conductor g259F corresponds to a boundary isolation region i259F. Each of the boundary isolation regions i251F and i259F defines an isolation region in the first-type active-region structure 80F at an intersection between the corresponding dummy gate-conductor and the first-type active-region structure 80F. The boundary isolation regions i251F and i259F in the first-type active-region structure 80F isolate the active regions (i.e., channel regions, source regions, and drain regions) of the first-type transistors in the logic circuit cell 101 from the active regions of other first-type transistors (in the first-type active-region structure 80F) in the neighboring logic circuit cells. The dummy gate-conductor g251B corresponds to a boundary isolation region i251B. The dummy gate-conductor g259B corresponds to a boundary isolation region i259B. Each of the boundary isolation regions i251B and i259B defines an isolation region in the second-type active-region structure 80B at an intersection between the corresponding dummy gate-conductor and the second-type active-region structure 80B. The boundary isolation regions i251B and i259B in the second-type active-region structure 80B isolate the active regions of the second-type transistors in the logic circuit cell 101 from the active regions of other second-type transistors (in the second-type active-region structure 80B) in the neighboring logic circuit cells.

The first horizontal cell boundary 202 of the logic circuit cell 101 extending in the X-direction overlaps with the second front-side power rail 40F and the second back-side power rail 40B when viewed in a direction normal to the substrate, i.e., when viewed in the plan view of FIG. 2A. In some embodiments, the first horizontal cell boundary 202 extends in the X-direction at the middle line of the second front-side power rail 40F and/or the second back-side power rail 40B.

The second horizontal cell boundary 208 of the logic circuit cell 101 extending in the X-direction overlaps with the first front-side power rail 20F and the first back-side power rail 20B when viewed in a direction normal to the substrate, i.e., when viewed in the plan view of FIG. 2A. In some embodiments, the second horizontal cell boundary 208 extends in the X-direction at the middle line of the first front-side power rail 20F and/or the first back-side power rail 20B.

In some embodiments, the cell height of the logic circuit cell 101 measured along the Y-direction is determined by the pitch distance of the first front-side power rail 20F and the second front-side power rail 40F or by the pitch distance of the first back-side power rail 20B and the second back-side power rail 40B. In some alternative embodiments, the cell height of the logic circuit cell 101 is determined by other elements in the logic circuit cell.

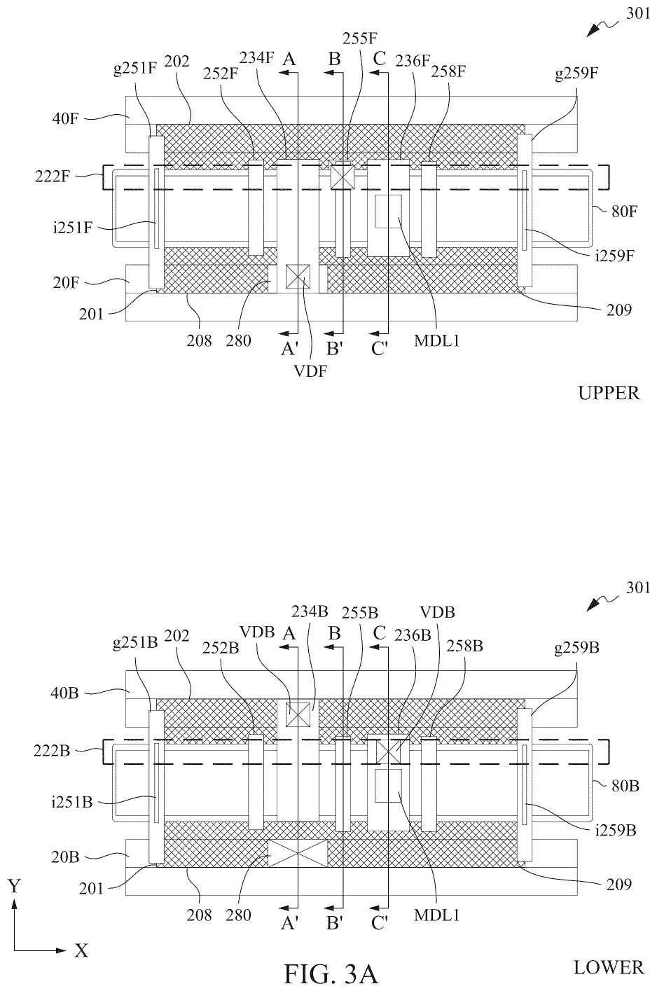

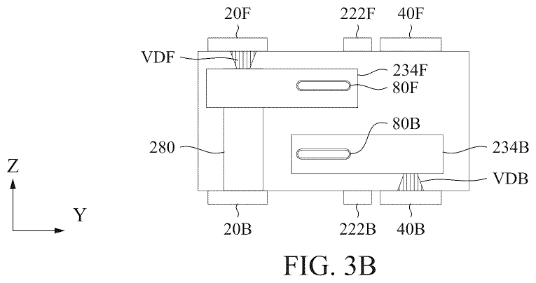

FIG. 3A is a layout diagram of a logic circuit cell 301, in accordance with some embodiments. In some embodiments, the logic circuit cell 301 corresponds to the logic circuit cell 101 of FIG. 1. In some embodiments, the logic circuit cell 301 corresponds to one or more of the logic circuit cells 102-107 of FIG. 1.

FIG. 3B is across-sectional view of the logic circuit cell 301, in accordance with some embodiments. Specifically, the cross-sectional view of the logic circuit cell 301 in cutting plane specified by the line A-A′ in FIG. 3A is depicted in FIG. 3B. Upper portion of line A-A′ in FIG. 3A (i.e., A) corresponds to right side in FIG. 3B.

FIG. 3A will be primarily described with reference to differences to FIG. 2A, and FIG. 3B will be primarily described with reference to differences to FIG. 2B.

In the upper portion of FIG. 3A (labeled ‘UPPER’), as compared to the upper portion of FIG. 2A, the logic circuit cell 301 further includes an upper via-connector VDF. Referring to the upper portion of FIG. 3A and referring to FIG. 3B, the upper via-connector VDF conductively connects the first front-side power rail 20F with the terminal-conductor 234F that intersects the first-type active-region structure 80F. The terminal-conductor 234F (which functions as the source terminal of the first-type transistor) is thus connected not only to the first back-side power rail 20B through the via-connector 280 (as in FIG. 2A), but also to the first front-side power rail 20F in FIG. 3A. The logic circuit cell 301 thus further provides a front-to-back power connection of the first front-side power rail 20F with the first back-side power rail 20B, relative to the structures of the logic circuit cell 101 in FIGS. 2A-2B.

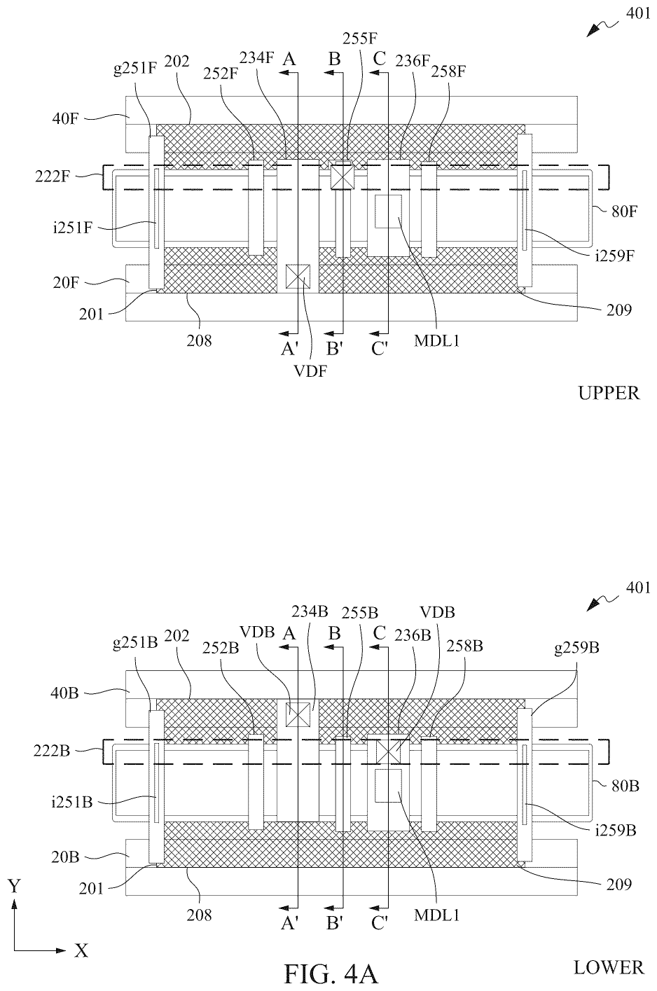

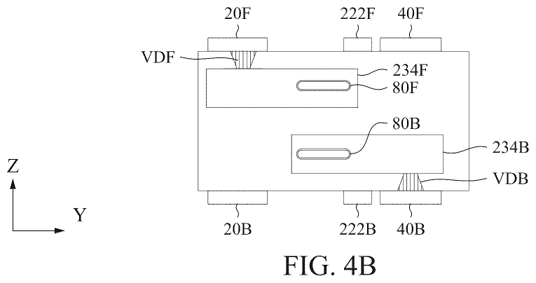

FIG. 4A is a layout diagram of a logic circuit cell 401, in accordance with some embodiments. In some embodiments, the logic circuit cell 401 corresponds to the logic circuit cell 101 of FIG. 1. In some embodiments, the logic circuit cell 401 corresponds to one or more of the logic circuit cells 102-107 of FIG. 1.

FIG. 4B is across-sectional view of the logic circuit cell 401, in accordance with some embodiments. Specifically, the cross-sectional view of the logic circuit cell 401 in cutting plane specified by the line A-A′ in FIG. 4A is depicted in FIG. 4B. Upper portion of line A-A′ in FIG. 4A (i.e., A) corresponds to right side in FIG. 4B.

FIG. 4A will be primarily described with reference to differences to FIG. 2A, and FIG. 4B will be primarily described with reference to differences to FIG. 2B.

In the upper portion of FIG. 4A (labeled ‘UPPER’), as compared to the upper portion of FIG. 2A, the logic circuit cell 301 further includes an upper via-connector VDF. However, referring to the upper and lower portions of FIG. 4A, the via-connector 280 is omitted, relative to FIG. 2A. Referring to the upper portion of FIG. 4A and referring to FIG. 4B, the upper via-connector VDF conductively connects the first front-side power rail 20F with the terminal-conductor 234F that intersects the first-type active-region structure 80F. However, relative to FIGS. 2A-2B, the terminal-conductor 234F (which functions as the source terminal of the first-type transistor) is not connected to the first back-side power rail 20B because the via-connector 280 is omitted.

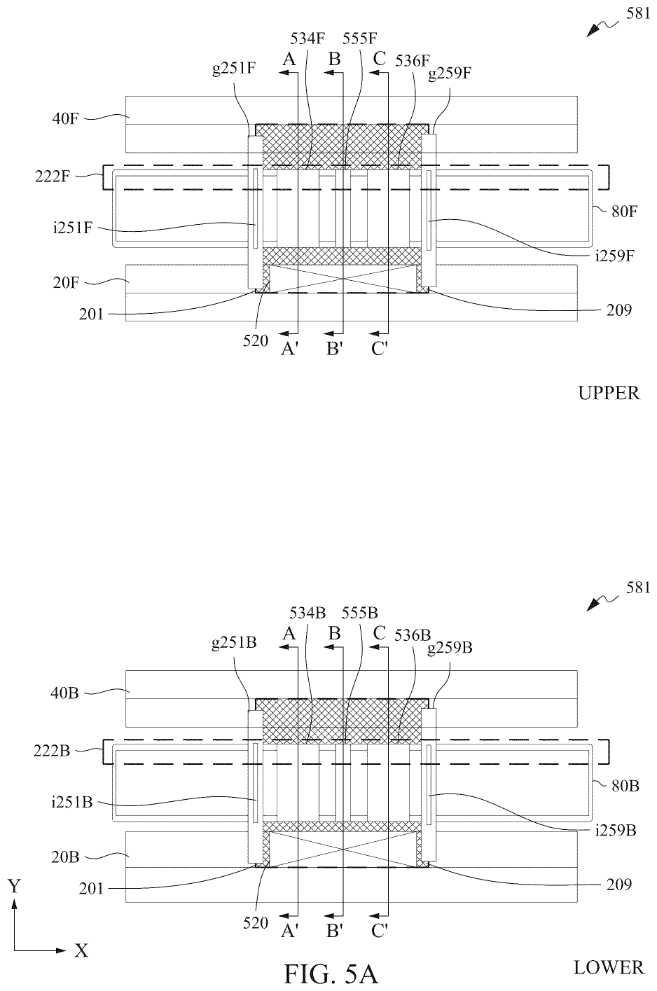

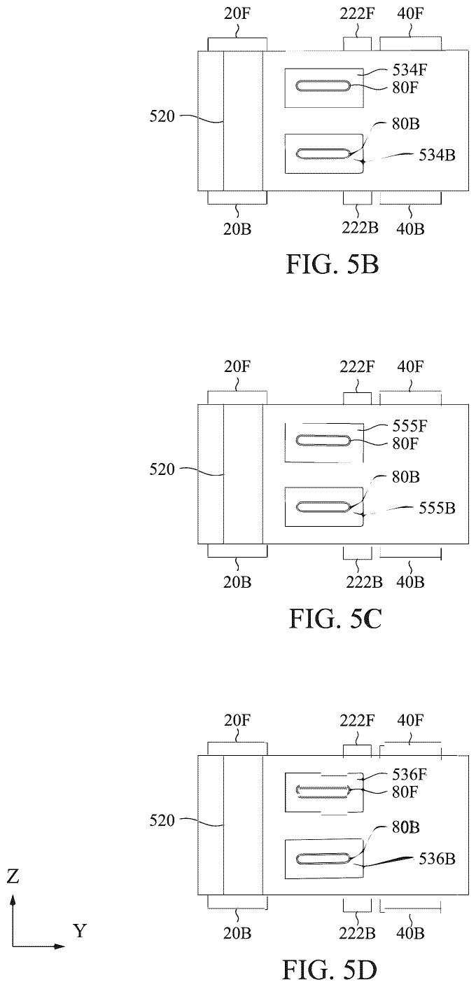

FIG. 5A is a layout diagram of a filler cell 581, in accordance with some embodiments. In some embodiments, the filler cell 581 corresponds to the filler cell 181 of FIG. 1. In some embodiments, the filler cell 581 corresponds to one or more of the filler cells 182-187 of FIG. 1.

FIGS. 5B-5D are cross-sectional views of the filler cell 581, in accordance with some embodiments. Specifically, the cross-sectional views of the filler cell 581 in cutting planes as specified by the lines A-A′, B-B′, and C-C′ in FIG. 5A are correspondingly depicted in FIG. 5B, FIG. 5C, and FIG. 5D. Upper portions of lines A-A′, B-B′, and C-C′ in FIG. 5A (i.e., A, B, and C) correspond to right sides in FIGS. 5B-5D.

FIGS. 5A-5D will be primarily described with reference to differences to FIGS. 2A-2D.

As discussed above in connection with the filler cells 181-187, the filler cell 581 includes a power via-connector which conductively connects a front-side power rail with a back-side power rail.

In FIGS. 5A-5D, the filler cell 581 is narrower in the X-axis direction than the logic circuit cell 101 of FIGS. 2A-D, e.g., the filler cell 581 is a smaller multiple of gate pitches relative to the logic circuit cell 101 of FIGS. 2A-2D. However, embodiments are not limited thereto. As discussed above, in some embodiments, the filler cells 181-187 are sized to have cell widths (in the X-direction or row-extending direction) that are based on spaces that remain in the rows 110A-110C after first placing the cells corresponding to the first, second, and third power tap structure regions 75A, 75B, and 75C are the logic circuit cells 101-107. Thus, in various embodiments, the filler cell 581 can be the same width as, or wider than, the logic circuit cell 101.

The filler cell 581 includes a power via-connector 520 that conductively connects the first front-side power rail 20F with the first back-side power rail 20B. Also, the filler cell 581 does not have any dynamic transistor and does not form an active circuit, and thus, relative to the logic circuit cell 101 of FIGS. 2A-D, gate-conductors 252F, 258F, 252B, and 258B are omitted.

The filler cell 581 includes terminal-conductors 534F and 534B (along line A-A′) and terminal-conductors 536F and 536B (along line C-C′). However, the filler cell 581 does not have any dynamic transistor. In the embodiment of FIGS. 5A-5D, the filler cell 581 includes a non-dynamic transistor in which the source, drain, and gate are not coupled to power or signal, e.g., to be in a floating state.

In detail, in the filler cell 581, the gate via-connector VGF and the lower via-connectors VDB of the logic circuit cell 101 of FIGS. 2A-D are omitted.

Further, in the filler cell 581, the terminal-conductors 534F and 536F are shortened in the Y-direction (row-height direction) and the terminal-conductors 534B and 536B are also shortened in the Y-direction, relative to the logic circuit cell 101 of FIGS. 2A-D, in view of the omission of connections to the power and signal lines. It will be appreciated, however, that the filler cell 581 has various lengths of the terminal-conductors 534F, 536F, 534B, and/or 536B in other embodiments, and the terminal-conductors 534F, 536F, 534B, and/or 536B need not be shorter than in the logic circuit cell 101. Further, in the filler cell 581, gate-conductors 555F and 555B are shortened in the Y-direction, relative to the logic circuit cell 101 of FIGS. 2A-D, in view of the omission of connection to the signal line. In some embodiments, shortening the terminal-conductors and/or the gate-conductors reduces overlap with front-side and or back-side power and/or signal lines to reduce parasitic capacitance and/or other undesirable coupling. It will be appreciated, however, that the filler cell 581 has various lengths of the gate-conductors 555F and/or 555B in other embodiments, and the gate-conductors 555F and/or 555B need not be shorter than in the logic circuit cell 101. An advantage of shortening the terminal-conductors and the gate-conductors is to space the terminal-conductors and the gate-conductors farther from the power via-connector 520, thus providing for easier fabrication and/or allowing for the power via-connector 520 to be made correspondingly larger in the row-height direction. Making the power via-connector 520 larger helps to reduce resistance of the connection between the first front-side power rail 20F and the first back-side power rail 20B.

In some embodiments, the segments of the first-and second-type active-region structures 80F and 80B in the filler cell 581 have a reduced cross-section relative to an overall average cross-section of the first-and second-type active-region structures along the row, or relative to a cross-section of segments of the first-and second-type active-region structures in logic circuit cells. In some embodiments, the segments of the first-and second-type active-region structures 80F and 80B in the filler cell 581 have a width along the Y-direction that is smaller than an average width of the first-and second-type active-region structures 80F and 80B.

In the filler cell 581, the gate-conductors 555F and 555B are separated from each other (i.e., not joined together) in the Z-direction, in view of the omission of connections to the power and signal lines. Further, the terminal-inter-connector MDL1 is omitted, relative to the logic circuit cell 101, in view of the omission of connections to the power and signal lines. Not joining the gate-conductors and omitting the terminal-inter-connector MDL1 simplifies fabrication of the filler cell 581.

In the filler cell 581, the power via-connector 520 is lengthened in the X-direction, relative to the logic circuit cell 101 of FIGS. 2A-D. Lengthening the power via-connector 520 helps to reduce resistance of the connection between the first front-side power rail 20F and the first back-side power rail 20B. As discussed above, the filler cell 581 can be made wider or narrower as suited to spaces remaining in the rows; the power via-connector 520 can be made wider or narrower in the X-direction, in correspondence with the width of the filler cell 581.

Although the filler cell 581 is shown with a single power via-connector 520 that is sized to the width of the filler cell 581 in the X-direction, in other embodiments multiple via-connectors are used rather than, or in combination with, changing the size of the via-connector in the X-direction. In some embodiments, a plurality of via-connectors each having a same X-Y footprint are arranged in the cell-width direction, e.g., with an increasing number of via-connectors being arranged in the filler cell with increasing width of the filler cell.

In some embodiments, the filler cell 581 has a first vertical cell boundary 201 extending in the Y-direction and passing through both a first isolation region i251B in the lower active-region structure and a second isolation region i251F in the upper active-region structure at a first end of a segment of the first-and second-type active-region structures 80F and 80B; and has a second vertical cell boundary 209 extending in the Y-direction and passing through both a third isolation region i259B in the lower active-region structure and a fourth isolation region i259F in the upper active-region structure at a second end of the segment of the first-and second-type active-region structures 80F and 80B.

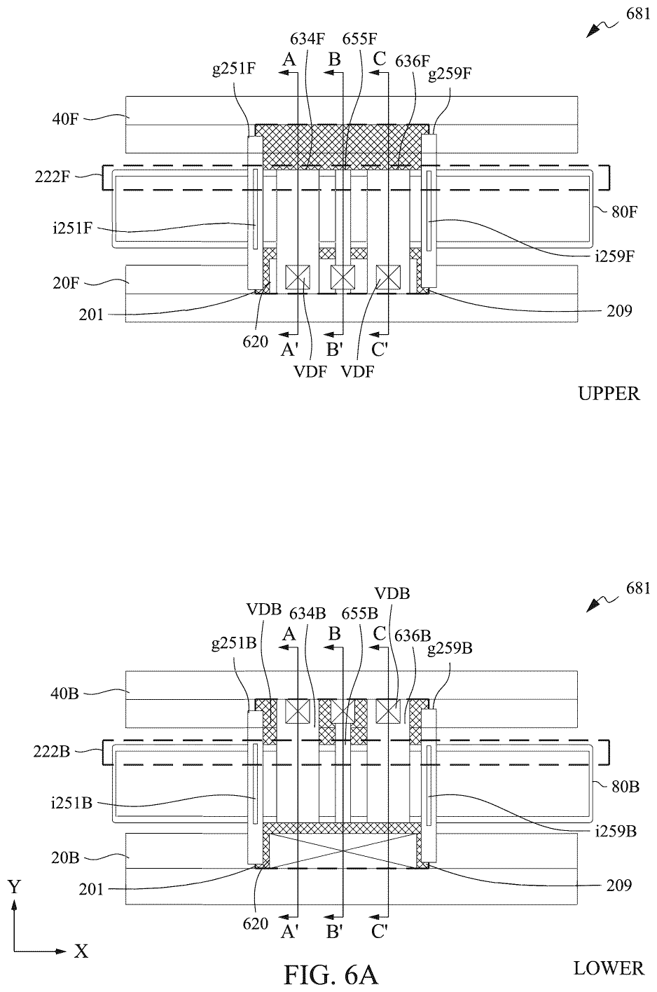

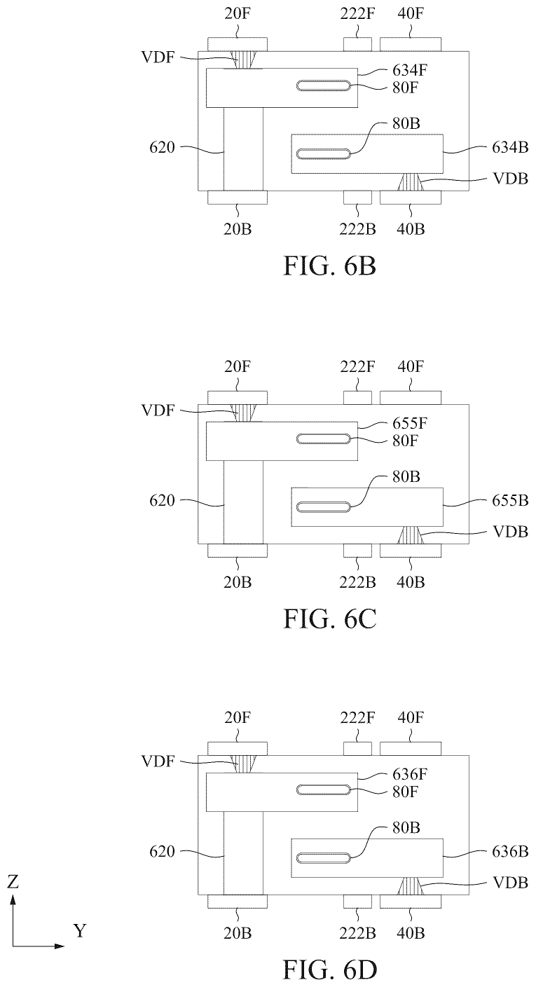

FIG. 6A is a layout diagram of a filler cell 681, in accordance with some embodiments. In some embodiments, the filler cell 681 corresponds to the filler cell 181 of FIG. 1. In some embodiments, the filler cell 681 corresponds to one or more of the filler cells 182-187 of FIG. 1.

FIGS. 6B-6D are cross-sectional views of the filler cell 681, in accordance with some embodiments. Specifically, the cross-sectional views of the filler cell 681 in cutting planes as specified by the lines A-A′, B-B′, and C-C′ in FIG. 6A are correspondingly depicted in FIG. 6B, FIG. 6C, and FIG. 6D. Upper portions of lines A-A′, B-B′, and C-C′ in FIG. 6A (i.e., A, B, and C) correspond to right sides in FIGS. 6B-6D.

FIGS. 6A-6D will be primarily described with reference to differences to FIGS. 2A-2D.

As discussed above in connection with the filler cells 181-187, the filler cell 681 includes a power via-connector which conductively connects a front-side power rail with a back-side power rail.

In FIGS. 6A-6D, the filler cell 681 is narrower in the X-axis direction than the logic circuit cell 101 of FIGS. 2A-D. However, embodiments are not limited thereto. As discussed above, in some embodiments, the filler cells 181-187 are sized to have cell widths (in the X-direction or row-extending direction) that are based on spaces that remain in the rows 110A-110C after first placing the cells corresponding to the first, second, and third power tap structure regions 75A, 75B, and 75C are the logic circuit cells 101-107. Thus, in various embodiments, the filler cell 681 can be the same width as, or wider than, the logic circuit cell 101.

The filler cell 681 includes a power via-connector 620 that conductively connects the first front-side power rail 20F with the first back-side power rail 20B. Also, the filler cell 681 does not have any dynamic transistor and does not form an active circuit, and thus, relative to the logic circuit cell 101 of FIGS. 2A-D, gate-conductors 252F, 258F, 252B, and 258B are omitted.

The filler cell 681 includes terminal-conductors 634F and 634B (along line A-A′) and terminal-conductors 636F and 636B (along line C-C′). However, the filler cell 681 does not have any dynamic transistor. In the embodiment of FIGS. 6A-6D, the filler cell 681 includes a non-dynamic transistor in which the source, drain, and gate are all coupled to power, e.g., to be in a tied, non-floating state.

In detail, in the filler cell 681, terminal-conductor 634F is conductively connected to the power via-connector 620 by addition of an upper via-connector VDF, relative to the logic circuit cell 101, in the same manner as described above for FIG. 3B. The upper via-connector VDF conductively connects the first front-side power rail 20F with the terminal-conductor 634F that intersects the first-type active-region structure 80F. The terminal-conductor 634F (which functions as the source terminal of the first-type transistor) is thus connected not only to the first back-side power rail 20B through the power via-connector 620 (as in FIG. 2A), but also to the first front-side power rail 20F in FIG. 6A.

Further, in the filler cell 681, terminal-conductor 636F is made longer in the Y-direction (cell-height direction) to overlap the first front-side power rail 20F and is conductively connected to the power via-connector 620 by addition of another upper via-connector VDF, relative to the logic circuit cell 101 of FIGS. 2A-D. The upper via-connector VDF conductively connects the first front-side power rail 20F with the terminal-conductor 636F that intersects the first-type active-region structure 80F. The terminal-conductor 636F (which functions as the drain terminal of the first-type transistor) is thus connected not only to the first back-side power rail 20B through the power via-connector 620, but also to the first front-side power rail 20F in FIG. 6A. The source and drain terminals of the first-type transistor are thus both tied to a same potential (the first front-side power rail 20F).

Further, in the filler cell 681, gate-conductor 655F is made longer in the Y-direction (cell-height direction) to overlap the first front-side power rail 20F and is conductively connected to the power via-connector 620 by addition of another upper via-connector VDF, relative to the logic circuit cell 101 of FIGS. 2A-D. The upper via-connector VDF conductively connects the first front-side power rail 20F with the gate-conductor 655F that intersects the first-type active-region structure 80F. The gate-conductor 655F (which functions as the gate of the first-type transistor) is thus connected not only to the first back-side power rail 20B through the power via-connector 620, but also to the first front-side power rail 20F in FIG. 6A. The source, drain, and gate terminals of the first-type transistor are thus all tied to a same potential (the first front-side power rail 20F).

Meanwhile, in the filler cell 681, terminal-conductor 634B is conductively connected to the second back-side power rail 40B by a lower via-connector VDB in the same manner as the logic circuit cell 101 of FIGS. 2A-D. The terminal-conductor 634B (which functions as the source terminal of the second-type transistor) is thus connected to the second back-side power rail 40B in the same manner as the logic circuit cell 101 of FIGS. 2A-D.

However, in the filler cell 681, terminal-conductor 636B is made longer in the Y-direction (cell-height direction) to overlap the second back-side power rail 40B and is conductively connected to the second back-side power rail 40B by a lower via-connector VDB, relative to the logic circuit cell 101 of FIGS. 2A-D. The terminal-conductor 636B is not connected to the lower-layer conducting line 222B, relative to the logic circuit cell 101 of FIGS. 2A-D. The lower via-connector VDB conductively connects the second back-side power rail 40B with the terminal-conductor 636B that intersects the second-type active-region structure 80B. The terminal-conductor 636B (which functions as the drain terminal of the second-type transistor) is thus connected to the second back-side power rail 40B. The source and drain terminals of the second-type transistor are thus both tied to a same potential (the second back-side power rail 40B).

Further, in the filler cell 681, gate-conductor 655B is made longer in the Y-direction (cell-height direction) to overlap the second back-side power rail 40B and is conductively connected to the second back-side power rail 40B by addition of another lower via-connector VDB, relative to the logic circuit cell 101 of FIGS. 2A-D. The lower via-connector VDB conductively connects the second back-side power rail 20B with the gate-conductor 655B that intersects the second-type active-region structure 80B. The gate-conductor 655B (which functions as the gate of the second-type transistor) is thus connected to the second back-side power rail 40B. The source, drain, and gate terminals of the second-type transistor are thus all tied to a same potential (the second back-side power rail 40B).

In the filler cell 681, the gate-conductors 655F and 655B are separated from each other (i.e., not joined together) in the Z-direction. Further, the terminal-inter-connector MDL1 is omitted, relative to the logic circuit cell 101 of FIGS. 2A-D. Not joining the gate-conductors and omitting the terminal-inter-connector MDL1 simplifies fabrication of the filler cell 681.

In the filler cell 681, the power via-connector 620 is lengthened in the X-direction, relative to the logic circuit cell 101 of FIGS. 2A-D. Lengthening the power via-connector 620 helps to reduce resistance of the connection between the first front-side power rail 20F and the first back-side power rail 20B. As discussed above regarding the filler cell 581, the filler cell 681 can be made wider or narrower as suited to spaces remaining in the rows; the power via-connector 620 can be made wider or narrower in the X-direction, in correspondence with the width of the filler cell 681.

Although the filler cell 681 is shown with a single power via-connector 620 that is sized to the width of the filler cell 681 in the X-direction, in other embodiments multiple via-connectors are used rather than, or in combination with, changing the size of the via-connector in the X-direction. In some embodiments, a plurality of via-connectors each having a same X-Y footprint are arranged in the cell-width direction, e.g., with an increasing number of via-connectors being arranged in the filler cell with increasing width of the filler cell.

In some embodiments, the filler cell 681 has a first vertical cell boundary 201 extending in the Y-direction and passing through both a first isolation region i251B in the lower active-region structure and a second isolation region i251F in the upper active-region structure at a first end of a segment of the first-and second-type active-region structures 80F and 80B; and has a second vertical cell boundary 209 extending in the Y-direction and passing through both a third isolation region i259B in the lower active-region structure and a fourth isolation region i259F in the upper active-region structure at a second end of the segment of the first-and second-type active-region structures 80F and 80B.

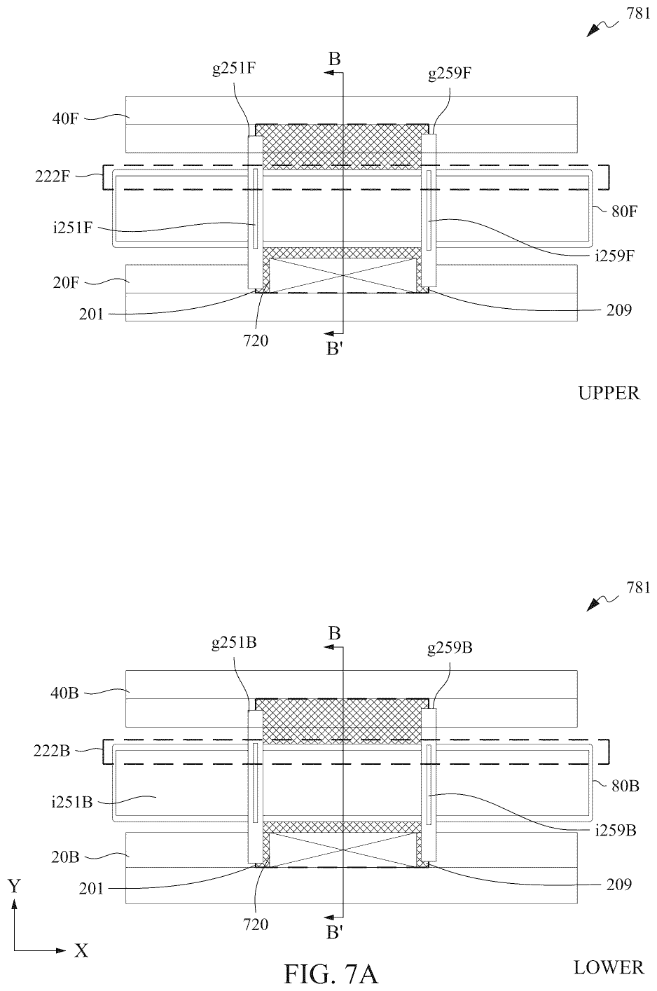

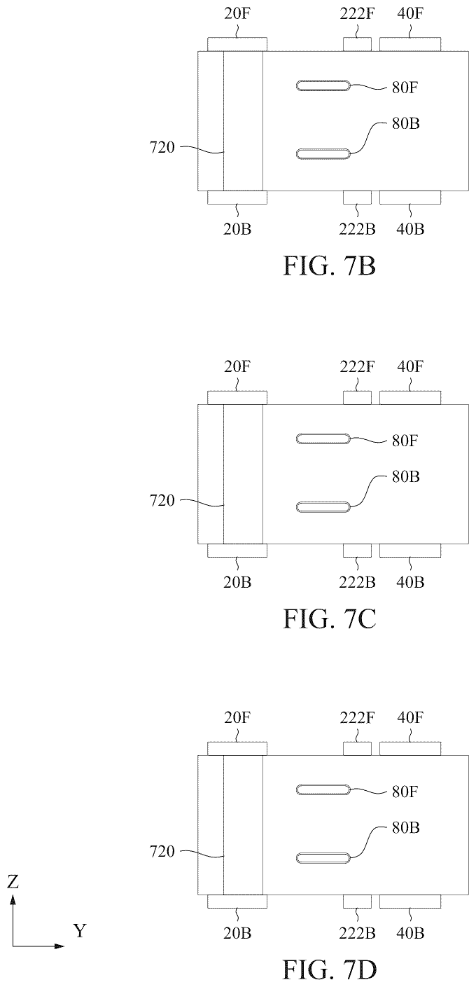

FIG. 7A is a layout diagram of a filler cell 781, in accordance with some embodiments. In some embodiments, the filler cell 781 corresponds to the filler cell 181 of FIG. 1. In some embodiments, the filler cell 781 corresponds to one or more of the filler cells 182-187 of FIG. 1.

FIGS. 7B-7D are cross-sectional views of the filler cell 781, in accordance with some embodiments. Specifically, the cross-sectional views of the filler cell 781 in cutting planes as specified by the lines A-A', B-B', and C-C′ in FIG. 7A are correspondingly depicted in FIG. 7B, FIG. 7C, and FIG. 7D. Upper portions of lines A-A', B-B', and C-C′ in FIG. 7A (i.e., A, B, and C) correspond to right sides in FIGS. 7B-7D.

FIGS. 7A-7D will be primarily described with reference to differences to FIGS. 2A-2D.

As discussed above in connection with the filler cells 181-187, the filler cell 781 includes a power via-connector which conductively connects a front-side power rail with a back-side power rail.

In FIGS. 7A-7D, the filler cell 781 is narrower in the X-axis direction than the logic circuit cell 101 of FIGS. 2A-D. However, embodiments are not limited thereto. As discussed above, in some embodiments, the filler cells 181-187 are sized to have cell widths (in the X-direction or row-extending direction) that are based on spaces that remain in the rows 110A-110C after first placing the cells corresponding to the first, second, and third power tap structure regions 75A, 75B, and 75C are the logic circuit cells 101-107. Thus, in various embodiments, the filler cell 781 can be the same width as, or wider than, the logic circuit cell 101.

The filler cell 781 includes a power via-connector 720 that conductively connects the first front-side power rail 20F with the first back-side power rail 20B. Also, the filler cell 781 does not have any dynamic transistor and does not form an active circuit, and thus, relative to the logic circuit cell 101 of FIGS. 2A-D, gate-conductors 252F, 258F, 252B, and 258B are omitted.

In the embodiment of FIGS. 7A-7D, the filler cell 781 does not include a transistor. In detail, although the first-and second-type active-region structures 80F and 80B are present in the filler cell 781, the terminal-conductors are omitted and the gate-conductors are omitted, relative to the logic circuit cell 101 of FIGS. 2A-D. In other embodiments (not shown in FIGS. 7A-7D), the first-t and second-type active-region structures 80F and 80B are also omitted in the filler cell 781.

In the filler cell 781, the power via-connector 720 is lengthened in the X-direction, relative to the logic circuit cell 101 of FIGS. 2A-D. Lengthening the power via-connector 720 helps to reduce resistance of the connection between the first front-side power rail 20F and the first back-side power rail 20B. As discussed above, the filler cell 781 can be made wider or narrower as suited to spaces remaining in the rows; the power via-connector 720 can be made wider or narrower in the X-direction, in correspondence with the width of the filler cell 781.

Although the filler cell 781 is shown with a single power via-connector 720 that is sized to the width of the filler cell 781 in the X-direction, in other embodiments multiple via-connectors are used rather than, or in combination with, changing the size of the via-connector in the X-direction. In some embodiments, a plurality of via-connectors each having a same X-Y footprint are arranged in the cell-width direction, e.g., with an increasing number of via-connectors being arranged in the filler cell with increasing width of the filler cell.

In some embodiments, the filler cell 781 has a first vertical cell boundary 201 extending in the Y-direction and passing through both a first isolation region i251B in the lower active-region structure and a second isolation region i251F in the upper active-region structure at a first end of a segment of the first-and second-type active-region structures 80F and 80B; and has a second vertical cell boundary 209 extending in the Y-direction and passing through both a third isolation region i259B in the lower active-region structure and a fourth isolation region i259F in the upper active-region structure at a second end of the segment of the first-and second-type active-region structures 80F and 80B.

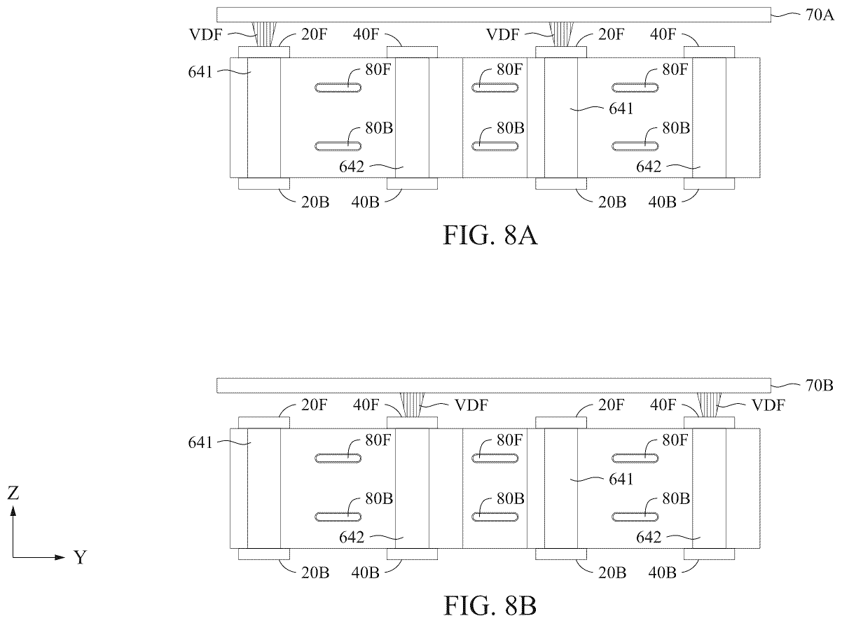

FIGS. 8A-8B are cross-sectional views of the integrated circuit 100, in accordance with some embodiments. Specifically, the cross-sectional views of the integrated circuit 100 in cutting planes as specified by the lines P-P′ and Q-Q′ in FIG. 1 are correspondingly depicted in FIG. 8A and FIG. 8B. Upper portions of lines P-P′ and Q-Q′ in FIG. 1 (i.e., P and Q) correspond to right sides in FIGS. 8A-8B.

Referring to FIGS. 1, 8A, and 8B, the integrated circuit 100 includes the power rails 20F/20B and 40F/40B extending in the X-direction. The first front-side power rail 20F vertically overlaps the first back-side power rail 20B (i.e., overlaps relative to the Z-direction), and the second front-side power rail 40F vertically overlaps the second back-side power rail 40B. The first and second front-side power rails 20F and 40F are in an upper conductive layer. The first and second back-side power rails 20B and 40B are in a lower conductive layer. The power rails 20F/20B are interlaced with the power rails 40F/40B relative to the Y-direction.

The first-type active-region structure 80F and the second-type active-region structure 80B vertically overlap one another and extend in the X-direction, and are interlaced with the power rails 20F/20B and 40F/40B relative to the Y-direction.

In the first power tap structure region 75A, the first vertical power line 70A is coupled to the first front-side power rails 20F of the first, second, and third rows 110, 110B, and 110C by corresponding upper via-conductors VDF that pass through a layer of inter layer dielectric. In the second power tap structure region 75B, the second vertical power line 70B is coupled to the second front-side power rails 40F of the first, second, and third rows 110A, 110B, and 110C by corresponding upper via-conductors VDF that pass through the layer of inter layer dielectric. In some embodiments, the vertical power lines are in a second or M1 metallization layer, the front-side power rails are in a first or M0 metallization layer, and the via-conductors VDF are in a first or VIA0 via layer.

In the first power tap structure region 75A and the second power tap structure region 75B, conductors 641 extend in a direction perpendicular to the substrate (Z-direction) to conductively connect the first front-side power rails 20F to the first back-side power rails 20B, and conductors 642 extend in the Z-direction to conductively connect the second front-side power rails 40F to the second back-side power rails 40B.

In FIGS. 8A-8B, the first and second power tap structure regions 75A and 75B do not include transistors. Accordingly, the conductors 641 and/or 642 can be made larger in the X-direction and/or the Y-direction, relative to what is shown in FIGS. 8A-8B. For example, in some embodiments the conductors 641 and 642 have a same dimension in the row-height direction (Y-direction) as the power rails 20F/20B and 40F/40B. Increasing the size (i.e., the X-Y footprint) of the conductors 641 and 642 reduces resistance between the front-side and back-side power rails.

In other embodiments, the number and/or size of the conductors 641 and 642 is reduced, and/or the row-direction pitch of the conductors 641 and 642 is increased, to provide additional logic circuit cell layout area, with filler cells providing additional front-back connections to wholly or partially compensate for reduced front-back conductivity resulting from the reduced number and/or size of the conductors 641 and 642, and/or the increased row-direction pitch of the conductors 641 and 642.

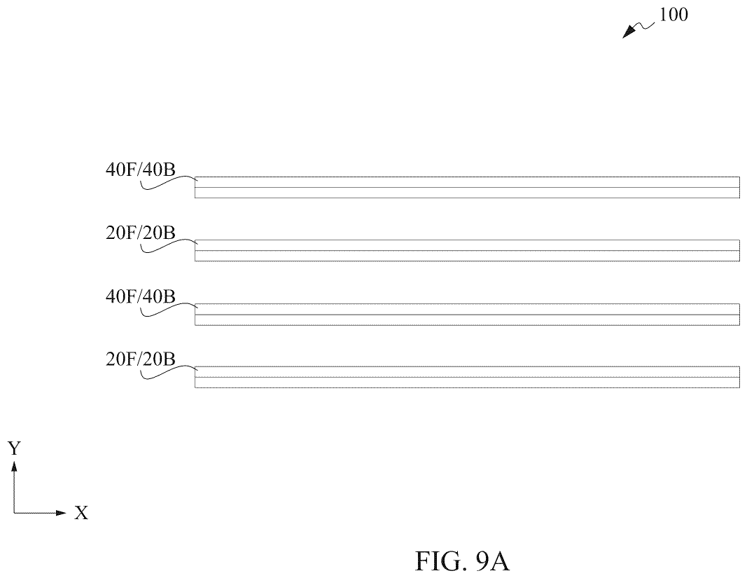

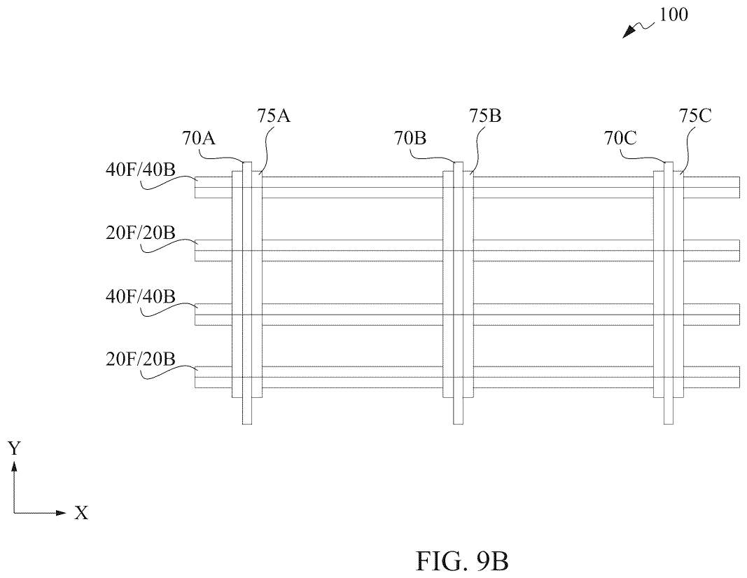

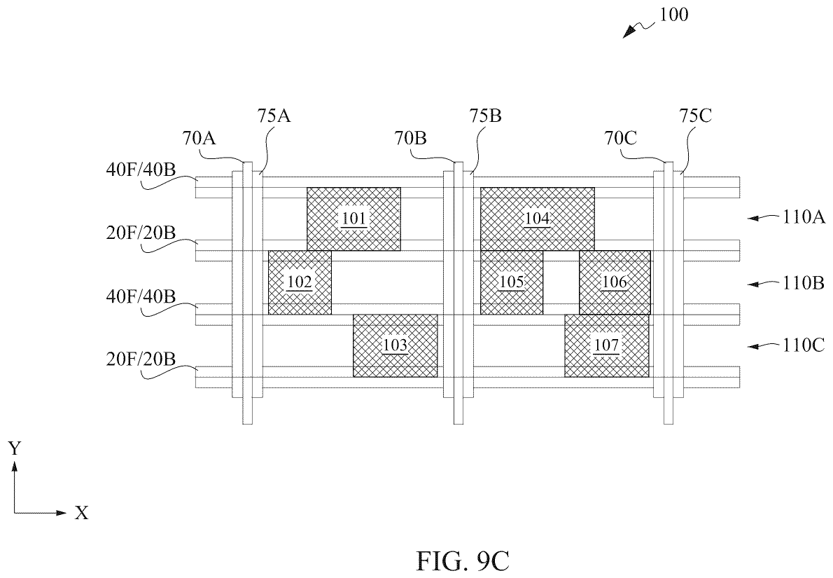

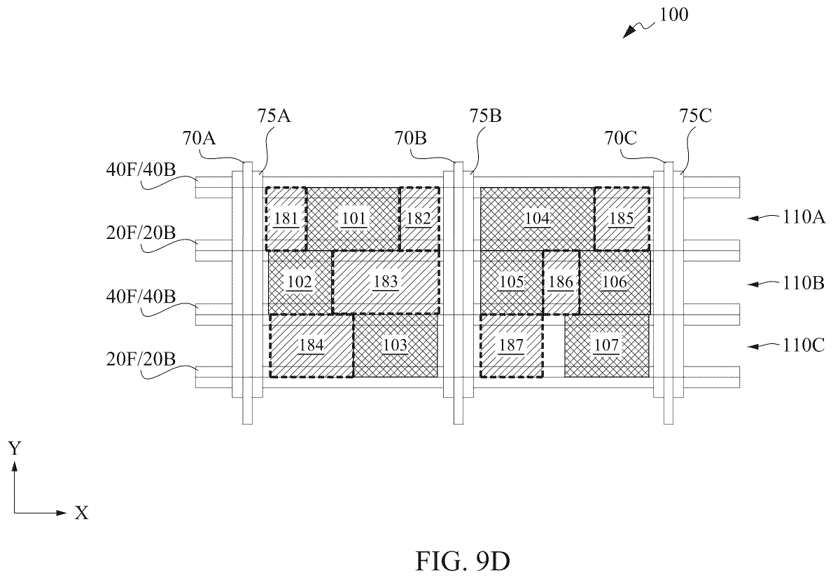

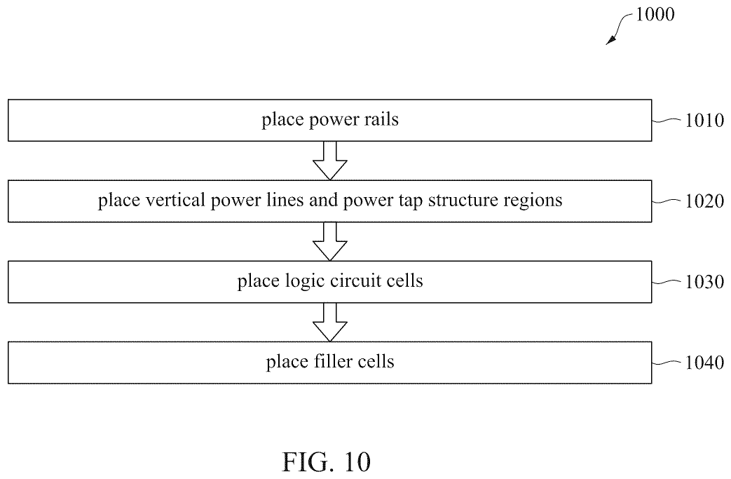

FIGS. 9A-9D are stages in forming a layout, in accordance with some embodiments. FIG. 10 is a flowchart of a method 1000 of forming a layout corresponding to FIGS. 9A-9D, in accordance with some embodiments. It is understood that additional operations may be performed before, during, and/or after the method 1000 depicted in FIG. 10, and that some other operations may only be briefly described herein.

In FIG. 9A and operation 1010 of the method 1000, the power rails 20F/20B and 40F/40B are arranged in the layout to extend in the X-direction. The first front-side power rail 20F is arranged to vertically overlap the first back-side power rail 20B (i.e., overlaps relative to the Z-direction), and the second front-side power rail 40F is arranged to vertically overlap the second back-side power rail 40B. The first and second front-side power rails 20F and 40F are placed in an upper conductive layer. The first and second back-side power rails 20B and 40B are placed in a lower conductive layer. The power rails 20F/20B are arranged to be interlaced with the power rails 40F/40B relative to the Y-direction.

In FIG. 9B and operation 1020 of the method 1000, the first, second, and third power tap structure regions 75A, 75B, and 75C are arranged to be spaced apart in sequence in the X-direction, each the first, second, and third power tap structure regions 75A, 75B, and 75C extending in the Y-direction to cross the first and second front-side power rails 20F and 40F. Also, the first, second, and third vertical power lines 70A, 70B, and 70C are arranged to be spaced apart in sequence in the X-direction, each of the first, second, and third vertical power lines 70A, 70B, and 70C extending in the Y-direction and vertically overlapping a corresponding one of the first, second, and third power tap structure regions 75A, 75B, and 75C.

In FIG. 9C and operation 1030 of the method 1000, the logic circuit cells 101-107 are arranged in the first, second, and third rows 110A, 110B, and 110C in spaces between the first, second, and third power tap structure regions 75A, 75B, and 75C.

In FIG. 9D and operation 1040 of the method 1000, the filler cells 181-187 are arranged in the first, second, and third rows 110A, 110B, and 110C in spaces between the logic circuit cells 101-107. In FIG. 9D, the filler cells 181-187 are sized based on spaces remaining in the rows 110A-110C after placing the logic circuit cells 101-107, i.e., the filler cells 181-187 are of various sizes. In other embodiments, the filler cells are all a same size and/or multiple smaller filler cells are placed in one space.

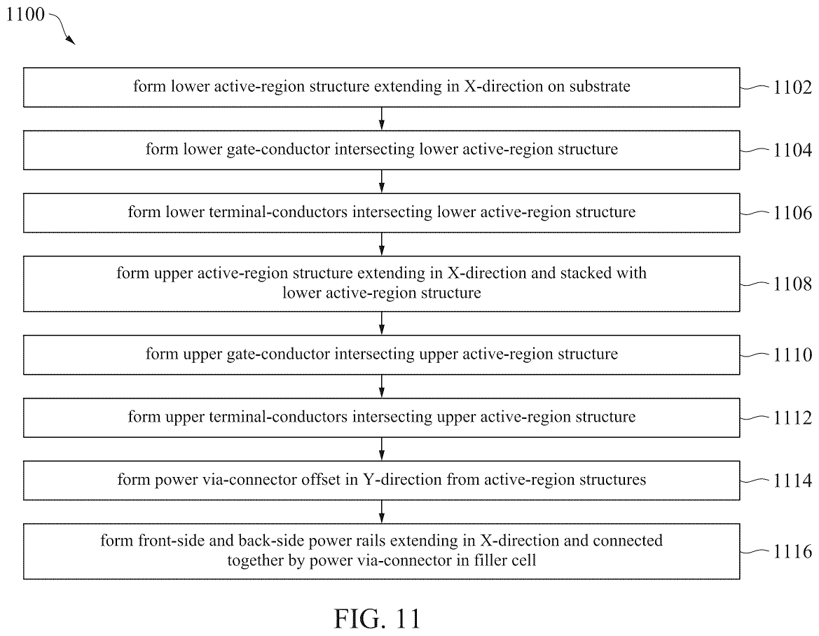

FIG. 11 is a flowchart of a method 1100 of fabricating an integrated circuit having a filler cell, in accordance with some embodiments. It is understood that additional operations may be performed before, during, and/or after the method 1100 depicted in FIG. 11, and that some other operations may only be briefly described herein.

In operation 1102 of the method 1100, a lower active-region structure extending in the X-direction is fabricated on a substrate. For example, with reference to FIGS. 5B-5D, the second-type active-region structure 80B is fabricated on a substrate in some embodiments.

In operation 1104 of the method 1100, a lower gate-conductor is formed intersecting the lower active-region structure. For example, with reference to FIGS. 5B-5D, the gate-conductor 555B is formed intersecting the second-type active-region structure 80B.

In operation 1106 of the method 1100, lower terminal-conductors are formed intersecting the second-type active-region structure 80B. For example, with reference to FIGS. 5B-5D, the terminal-conductors 534B and 536B are formed intersecting the second-type active-region structure 80B.

In operation 1108 of the method 1100, an upper active-region structure extending in the X-direction is fabricated to be stacked with the lower active-region structure. For example, with reference to FIGS. 5B-5D, the first-type active-region structure 80F is fabricated to be stacked with the second-type active-region structure 80B.

In operation 1110 of the method 1100, an upper gate-conductor is formed intersecting the upper active-region structure. For example, with reference to FIGS. 5B-5D, the gate-conductor 555F is formed intersecting the first-type active-region structure 80F.

In operation 1112 of the method 1100, upper terminal-conductors are formed intersecting the upper active-region structure. For example, with reference to FIGS. 5B-5D, the terminal-conductors 534F and 534B are formed intersecting the first-type active-region structure 80F.

In operation 1114 of the method 1100, a power via-conductor is formed in the filler cell to be offset in the Y-direction from the lower and upper active-region structures. For example, with reference to FIGS. 5B-5D, the power via-connector 520 is formed to be offset in the Y-direction from the first-and second-type active-region structures 80F and 80B.

In operation 1116 of the method 1100, front-side and back-side power rails are formed to extend in the X-direction while being connected together by the power via-conductor in the filler cell. For example, with reference to FIGS. 5B-5D, the first front-side power rail 20F and the first back-side power rail 20B are formed to extend in the X-direction while being connected together by the power via-connector 520.

In some embodiments, the method 1100 is used to fabricate an integrated circuit having the filler cell 581. It will be appreciated that the method 1100 is not limited to the order of operations described in FIG. 11. Further, various operations can be omitted or replaced in other embodiments, e.g., operations 1104, 1106, 1110, and 1112 can be omitted while fabricating an integrated circuit having the filler cell 781.

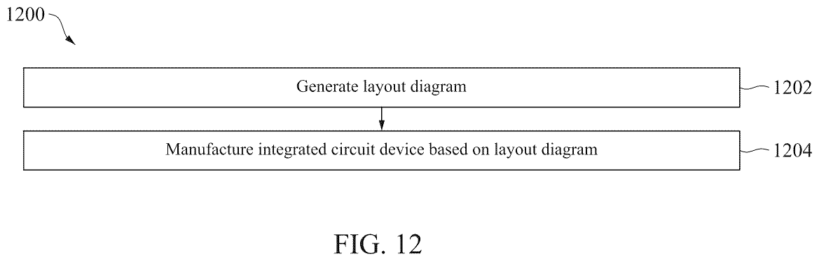

FIG. 12 is a flowchart of a method 1200 of manufacturing a semiconductor device according to some embodiments.

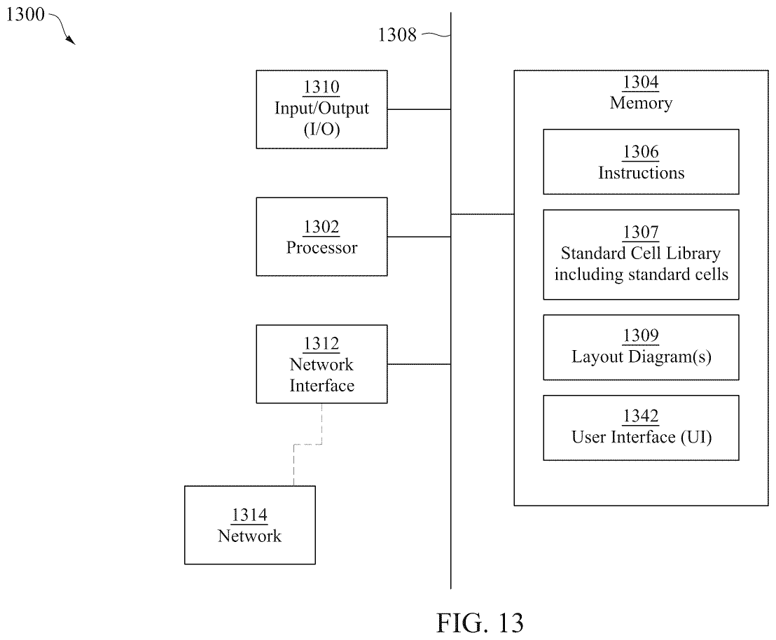

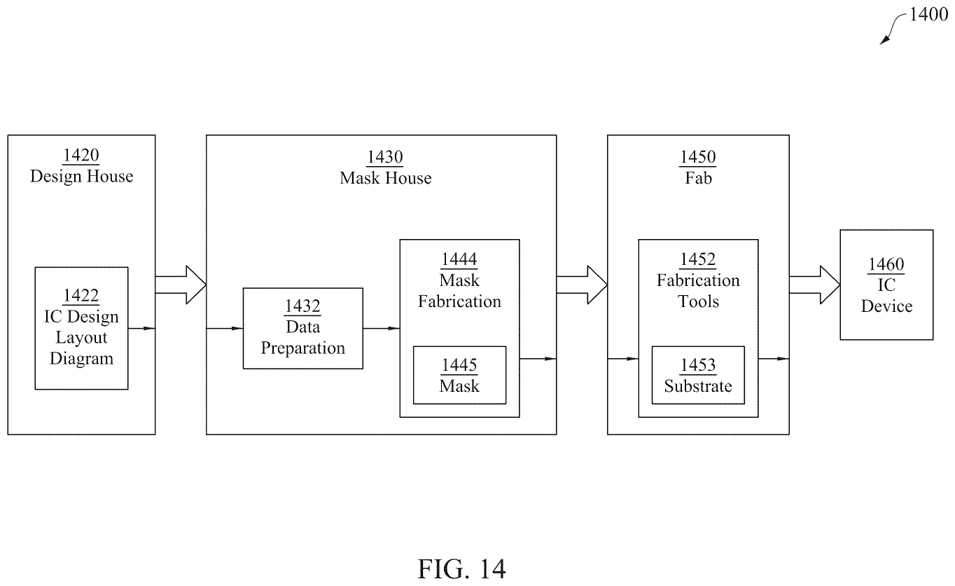

Method 1200 is implementable, for example, using EDA system 1300 (FIG. 13, discussed below) and an integrated circuit (IC) manufacturing system 1400 (FIG. 14, discussed below), in accordance with some embodiments. Examples of a semiconductor device which can be manufactured according to method 1200 include one or more of the integrated circuits described above.

In FIG. 12, method 1200 includes blocks 1202-1204. At operation 1202, a layout diagram is generated which, among other things, includes one or more of layout diagrams disclosed herein, or the like.

Operation 1202 is implementable, for example, using EDA system 1300 (FIG. 13, discussed below), in accordance with some embodiments. In some embodiments, operation 1202 includes generating shapes corresponding to structures in a semiconductor diagram which are to be represented.

At operation 1204, based on the layout diagram, at least one of (A) one or more photolithographic exposures are made or (B) one or more semiconductor masks are fabricated or (C) one or more components in a layer of an integrated circuit (IC) device, e.g., a semiconductor device, are fabricated.

FIG. 13 is a block diagram of an electronic design automation (EDA) system 1300 in accordance with some embodiments. The EDA system 1300 is usable to design one or more of the integrated circuits described above.

In some embodiments, the EDA system 1300 includes an APR system. In some embodiments, EDA system 1300 is or includes a general purpose computing device including a hardware processor 1302 and a non-transitory, computer-readable storage medium 1304. The computer-readable storage medium 1304 is encoded with, i.e., stores, computer program code 1306, i.e., a set of executable instructions. Execution of the instructions 1306 by the processor 1302 represents (at least in part) an EDA tool which implements a portion or all of the methods described herein in accordance with one or more embodiments (hereinafter, the noted processes and/or methods).

In some embodiments, methods described herein of designing layout diagrams representing wire routing arrangements are implementable using the EDA system 1300.

In some embodiments, execution of instructions 1306 by the processor 1302 represents (at least in part) an IC device design system which implements a portion or all of one or more of the noted processes and/or methods.

In some embodiments, a computer program product includes the non-transitory, computer-readable storage medium 1304 storing instructions therein that, when executed by the processor 1302, cause the processor 1302 to perform a cell placement operation.

The processor 1302 is electrically coupled to computer-readable storage medium 1304 via a bus 1308. The processor 1302 is also electrically coupled to an input/output (I/O) interface 1310 by bus 1308. A network interface 1312 is also electrically connected to the processor 1302 via the bus 1308. The network interface 1312 is connected to a network 1314, so that the processor 1302 and computer-readable storage medium 1304 are capable of connecting to external elements via the network 1314. The processor 1302 is configured to execute computer program code 1306 encoded in the computer-readable storage medium 1304 in order to cause the EDA system 1300 to be usable for performing a portion or all of the noted processes and/or methods. In some embodiments, the processor 1302 is a central processing unit (CPU), a multi-processor, a distributed processing system, an application specific integrated circuit (ASIC), and/or a suitable processing unit.

In some embodiments, the computer-readable storage medium 1304 is an electronic, magnetic, optical, electromagnetic, infrared, and/or a semiconductor system (or apparatus or device). In some embodiments, the computer-readable storage medium 1304 includes a semiconductor or solid-state memory, a magnetic tape, a removable computer diskette, a random-access memory (RAM), a read-only memory (ROM), a rigid magnetic disk, and/or an optical disk. In some embodiments using optical disks, computer-readable storage medium 1304 includes a compact disc read-only memory (CD-ROM), a compact disc-read/write (CD-R/W), and/or a digital video disc (DVD).

In some embodiments, the computer-readable storage medium 1304 stores computer program code 1306 (instructions) configured to cause the EDA system 1300 (where such execution represents (at least in part) the EDA tool) to be usable for performing a portion or all of the noted processes and/or methods. In some embodiments, the computer-readable storage medium 1304 also stores information that facilitates performing a portion or all of the noted processes and/or methods. In some embodiments, the computer-readable storage medium 1304 stores a library 1307 of standard cells including such standard cells as disclosed herein. In some embodiments, the computer-readable storage medium 1304 stores one or more layout diagrams 1309 corresponding to one or more layouts disclosed herein.

The EDA system 1300 includes the I/O interface 1310. The I/O interface 1310 is coupled to external circuitry. In some embodiments, the I/O interface 1310 includes a keyboard, keypad, mouse, trackball, trackpad, touchscreen, and/or cursor direction keys for communicating information and commands to the processor 1302.

The EDA system 1300 also includes the network interface 1312 coupled to the processor 1302. The network interface 1312 allows the EDA system 1300 to communicate with the network 1314, to which one or more other computer systems are connected. The network interface 1312 includes wireless network interfaces such as BLUETOOTH, WIFI, WIMAX, GPRS, or WCDMA; or wired network interfaces such as ETHERNET, USB, or IEEE-1364. In some embodiments, a portion or all of noted processes and/or methods, is implemented in two or more EDA systems 1300.

The EDA system 1300 is configured to receive information through the I/O interface 1310. The information received through the I/O interface 1310 includes one or more of instructions, data, design rules, libraries of standard cells, and/or other parameters for processing by the processor 1302. The information is transferred to the processor 1302 via the bus 1308. The EDA system 1300 is configured to receive information related to a user interface (UI) through the I/O interface 1310. The information is stored in computer-readable storage medium 1304 as UI 1342.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1300. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 14 is a block diagram of an IC manufacturing system 1400, and an IC manufacturing flow associated therewith according to some embodiments. In some embodiments, based on a layout diagram, at least one of (A) one or more semiconductor masks or (B) at least one component in a layer of a semiconductor integrated circuit is fabricated using the IC manufacturing system 1400.

In FIG. 14, the IC manufacturing system 1400 includes entities, such as a design house 1420, a mask house 1430, and an IC manufacturer/fabricator (“fab”) 1450, that interact with one another in the design, development, and manufacturing cycles and/or services related to manufacturing an IC device 1460. The entities in IC manufacturing system 1400 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of the design house 1420, the mask house 1430, and the IC fab 1450 is owned by a single larger company. In some embodiments, two or more of the design house 1420, the mask house 1430, and the IC fab 1450 coexist in a common facility and use common resources.

The design house (or design team) 1420 generates an IC design layout diagram 1422 based on the noted processes and/or methods discussed above. The IC design layout diagram 1422 includes various geometrical patterns that correspond to patterns of metal, oxide, or semiconductor layers that make up the various components of the IC device 1460 to be fabricated. The various layers combine to form various IC features. For example, a portion of the IC design layout diagram 1422 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. The design house 1420 implements a proper design procedure to form the IC design layout diagram 1422. The design procedure includes one or more of logic design, physical design or place and route. The IC design layout diagram 1422 is presented in one or more data files having information of the geometrical patterns. For example, the IC design layout diagram 1422 can be expressed in a GDSII file format or DFII file format.

The mask house 1430 includes mask data preparation 1432 and mask fabrication 1444. The mask house 1430 uses the IC design layout diagram 1422 to manufacture one or more masks 1445 to be used for fabricating the various layers of the IC device 1460 according to the IC design layout diagram 1422. The mask house 1430 performs the mask data preparation 1432, where the IC design layout diagram 1422 is translated into a representative data file (RDF). Mask data preparation 1432 provides the RDF to the mask fabrication 1444. Mask fabrication 1444 includes a mask writer. A mask writer converts the RDF to an image on a substrate, such as a mask (reticle) 1445 or a substrate 1453, e.g., a semiconductor wafer. The IC design layout diagram 1422 is manipulated by the mask data preparation 1432 to comply with particular characteristics of the mask writer and/or requirements of the IC fab 1450. In FIG. 14, the mask data preparation 1432 and the mask fabrication 1444 are illustrated as separate elements. In some embodiments, the mask data preparation 1432 and the mask fabrication 1444 can be collectively referred to as mask data preparation.

In some embodiments, the mask data preparation 1432 includes optical proximity correction (OPC) which uses lithography enhancement techniques to compensate for image errors, such as those that can arise from diffraction, interference, other process effects and the like. OPC adjusts the IC design layout diagram 1422. In some embodiments, the mask data preparation 1432 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 1432 includes a mask rule checker (MRC) that checks the IC design layout diagram 1422 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 1422 to compensate for limitations during the mask fabrication 1444, which may undo part of the modifications performed by OPC in order to meet mask creation rules.

In some embodiments, the mask data preparation 1432 includes lithography process checking (LPC) that simulates processing that will be implemented by the IC fab 1450 to fabricate the IC device 1460. LPC simulates this processing based on the IC design layout diagram 1422 to create a simulated manufactured device, such as the IC device 1460. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are be repeated to further refine the IC design layout diagram 1422.

It should be understood that the above description of the mask data preparation 1432 has been simplified for the purposes of clarity. In some embodiments, the mask data preparation 1432 includes additional features such as a logic operation (LOP) to modify the IC design layout diagram 1422 according to manufacturing rules. Additionally, the processes applied to the IC design layout diagram 1422 during the mask data preparation 1432 may be executed in a variety of different orders.

After the mask data preparation 1432 and during the mask fabrication 1444, the mask 1445 or a group of masks 1445 are fabricated based on the modified IC design layout diagram 1422. In some embodiments, the mask fabrication 1444 includes performing one or more lithographic exposures based on the IC design layout diagram 1422. In some embodiments, an electron-beam (e-beam) or a mechanism of multiple e-beams is used to form a pattern on the mask (photomask or reticle) 1445 based on the modified IC design layout diagram 1422. The mask 1445 can be formed in various technologies. In some embodiments, the mask 1445 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of the mask 1445 includes a transparent substrate (e.g., fused quartz) and an opaque material (e.g., chromium) coated in the opaque regions of the binary mask. In another example, the mask 1445 is formed using a phase shift technology. In a phase shift mask (PSM) version of the mask 1445, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 1444 is used in a variety of processes. For example, in some embodiments the mask(s) is used in an ion implantation process to form various doped regions in the substrate 1453, in an etching process to form various etching regions in the substrate 1453, and/or in other suitable processes.

The IC fab 1450 is an IC fabrication business that includes one or more manufacturing facilities for the fabrication of a variety of different IC products. In some embodiments, the IC fab 1450 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

The IC fab 1450 includes wafer fabrication tools 1452 configured to execute various manufacturing operations on the substrate 1453 such that the IC device 1460 is fabricated in accordance with the mask(s), e.g., the mask 1445. In some embodiments, the wafer fabrication tools 1452 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

The IC fab 1450 uses the mask(s) 1445 fabricated by the mask house 1430 to fabricate the IC device 1460. Thus, the IC fab 1450 at least indirectly uses the IC design layout diagram 1422 to fabricate the IC device 1460. In some embodiments, the substrate 1453 is fabricated by the IC fab 1450 using the mask(s) 1445 to form the IC device 1460. In some embodiments, the IC fabrication includes performing one or more lithographic exposures based at least indirectly on the IC design layout diagram 1422. In some embodiments, the substrate 1453 includes a silicon substrate or other proper substrate having material layers formed thereon. In some embodiments, the substrate 1453 further includes one or more of various doped regions, dielectric features, multilevel interconnects, and the like (formed at subsequent manufacturing steps).

Details regarding an IC manufacturing system (e.g., IC manufacturing system 1400 of FIG. 14), and an IC manufacturing flow associated therewith are found, e.g., in U.S. Pat. No. 9,256,709, granted Feb. 9, 2016, U.S. Pre-Grant Publication No. 2015/0278429 A1, published Oct. 1, 2015, U.S. Pre-Grant Publication No. 2014/0040838 A1, published Feb. 6, 2014, and U.S. Pat. No. 7,260,442, granted Aug. 21, 2007, the entireties of each of which are hereby incorporated by reference.

In some embodiments, an integrated circuit device includes: a first-type active-region semiconductor structure extending in a first direction parallel to a surface of a substrate; a second-type active-region semiconductor structure, extending in the first direction, stacked with the first-type active-region semiconductor structure and shifted from the first-type active-region semiconductor structure along a normal direction that is perpendicular to a surface of the substrate; a front-side power rail in a front-side conductive layer above both the first-type active region semiconductor structure and the second-type active-region semiconductor structure; a back-side power rail in a back-side conductive layer below both the first-type active region semiconductor structure and the second-type active-region semiconductor structure; and a filler cell having therein a power via-connector which extends in the third direction and conductively connecting the front-side power rail with the back-side power rail. In some embodiments, the filler cell has one or more transistors therein, and each of the transistors has a channel state thereof configured to be static and fixed over time. In some embodiments, the filler cell has no transistors therein, i.e., is free of or absent of any transistors.

In some embodiments, a complementary field-effect transistor (CFET) device includes: a top device disposed at a front side and configured to operate according to a power signal; a bottom device disposed at a back side and configured to operate according to the power signal; a first power track disposed at the front side; a second power track disposed at the back side; and a power via configured to transmit the power signal from the second power track to the first power track and is separated from each of the top device and the bottom device in a cross-sectional view.

In some embodiments, an integrated circuit device includes: a first stack of active-region structures extending in a first direction parallel to a surface of a substrate, the first stack of active-region structures including a lower active-region structure and an upper active-region structure stacked with each other on the substrate along a third direction perpendicular to the substrate; a front-side power rail extending in the first direction in an upper conductive layer above both the lower active-region structure and the upper active-region structure; a back-side power rail extending in the first direction in a lower conductive layer below both the lower active-region structure and the upper active-region structure; an array of vertical power lines, wherein each vertical power line in the array of vertical power lines extends in a second direction parallel to the surface of a substrate in a conductive layer which is different from the upper conductive layer and the lower conductive layer, the second direction being perpendicular to the first direction; and a filler cell having therein a segment of the first stack of active-region structures and having therein a power via-connector which extends in the third direction and conductively connects the front-side power rail with the back-side power rail, and wherein the filler cell is between two of the vertical power lines.

In some embodiments, the segment of the first stack of active-region structures in the filler cell has a width along the second direction smaller than an average width of the first stack of active-region structures. In some embodiments, either the front-side power rail or the back-side power rail is connected to a vertical power line in the array of vertical power lines with a via-connector passing through a layer of inter layer dielectric. In some embodiments, none of the vertical power lines pass across the filler cell. In some embodiments, the filler cell is free of any transistor. In some embodiments, the filler cell has one or more transistors therein, and each of the transistors in the filler cell has a channel thereof configured in a static state which remains unchanged over time. In some embodiments, the filler cell has one or more transistors therein, and each of the transistors in the filler cell has a gate terminal thereof configured either as a floating node or as a voltage node having a constant voltage. In some embodiments, the integrated circuit device further includes multiple logic circuit cells, and the filler cell is logically decoupled from each of the multiple logic circuit cells. In some embodiments, the filler cell further includes: a first vertical cell boundary extending in the second direction and passing through both a first isolation region in the lower active-region structure and a second isolation region in the upper active-region structure at a first end of the segment of the first stack of active-region structures; and a second vertical cell boundary extending in the second direction and passing through both a third isolation region in the lower active-region structure and a fourth isolation region in the upper active-region structure at a second end of the segment of the first stack of active-region structures. In some embodiments, the integrated circuit device further includes: a second stack of active-region structures extending in the first direction; and a third stack of active-region structures extending in the first direction, wherein the first stack of active-region structures extends in the first direction between the second stack of active-region structures and the third stack of active-region structures, and wherein each vertical power line in the array of vertical power lines extends across each of the first stack, the second stack, and the third stack of active-region structures. In some embodiments, none of the second stack of active-region structures and the third stack of active-region structures passes through the filler cell. In some embodiments, the integrated circuit device further includes a logic circuit cell adjacent to the filler cell, the logic circuit cell having therein a segment of the second stack of active-region structures, the filler cell having a vertical cell boundary extending in the second direction along a reference line which is between two vertical cell boundaries of the logic circuit cell. In some embodiments, each of the lower active-region structure and the upper active-region structure has therein multiple nano-sheets extending in the first direction. In some embodiments, each of the lower active-region structure and the upper active-region structure has therein multiple nano-wires extending in the first direction. In some embodiments, the integrated circuit includes: first-type transistors having channels thereof in the lower active-region structure; and second-type transistors having channels thereof in the upper active-region structure. In some embodiments, the first-type transistors are PMOS transistors, and the second-type transistors are NMOS transistors. In some embodiments, the first-type transistors are NMOS transistors, and the second-type transistors are PMOS transistors.

In some embodiments, an integrated circuit device includes: multiple stacks of active-region structures each extending in a first direction parallel to a surface of a substrate, where the multiple stacks of active-region structures include a first stack of active-region structures extending in the first direction between a second stack of active-region structures and a third stack of active-region structures; a front-side power rail in an upper conductive layer above the multiple stacks of active-region structures; a back-side power rail in a lower conductive layer below the multiple stacks of active-region structures; a filler cell having therein a segment of the first stack of active-region structures and having therein a power via-connector which conductively connects the front-side power rail with the back-side power rail, wherein the power via-connector extends in a third direction perpendicular to the surface of the substrate, and wherein the filler cell is free of any dynamic transistor, a dynamic transistor being a transistor configured to have a channel state thereof changing with time; and a logic circuit cell adjacent to the filler cell, the logic circuit cell having therein a segment of the second stack of active-region structures, wherein the filler cell has a vertical cell boundary extending in a second direction along a reference line which is between two vertical cell boundaries of the logic circuit cell, the second direction being perpendicular to the first direction.

In some embodiments, the filler cell is free of any transistor. In some embodiments, each of the second stack of active-region structures and the third stack of active-region structures is adjacent to the first stack of active-region structures, and none of the second stack of active-region structures and the third stack of active-region structures passes through the filler cell. In some embodiments, each stack of active-region structures in the multiple stacks of active-region structures includes a lower active-region structure and an upper active-region structure stacked with each other on the substrate along the third direction perpendicular to the substrate, the lower active-region structure has therein channels of first-type transistors, and the upper active-region structure has therein channels of second-type transistors. In some embodiments, the segment of the first stack of active-region structures is bounded between a first vertical cell boundary and a second vertical cell boundary of the filler cell, and each of the first vertical cell boundary and the second vertical cell boundary extends in the second direction and intersects the first stack of active-region structures. In some embodiments, the filler cell is bounded between a first horizontal cell boundary extending in the first direction and a second horizontal cell boundary extending in the first direction.

In some embodiments, an integrated circuit device includes: a first stack of active-region structures extending in a first direction parallel to a surface of a substrate, the first stack of active-region structures including a lower active-region structure and an upper active-region structure stacked with each other on the substrate along a third direction perpendicular to the substrate, wherein the lower active-region structure has therein channels of first-type transistors, and wherein the upper active-region structure has therein channels of second-type transistors; a front-side power rail in an upper conductive layer above both the lower active-region structure and the upper active-region structure; a back-side power rail in a lower conductive layer below both the lower active-region structure and the upper active-region structure; and a filler cell having therein a segment of the first stack of active-region structures and having therein a power via-connector which extends in the third direction and conductively connects the front-side power rail with the back-side power rail, wherein the filler cell is free of any dynamic transistor, a dynamic transistor being a transistor configured to have a channel state thereof changing with time.

In some embodiments, the filler cell is free of any transistor. In some embodiments, the segment of the first stack of active-region structures is bounded between a first vertical cell boundary and a second vertical cell boundary of the filler cell, and each of the first vertical cell boundary and the second vertical cell boundary extends in a second direction and passes through an isolation region in the lower active-region structure and an isolation region in the upper active-region structure while intersecting the first stack of active-region structures.

In some embodiments, a method of fabricating an integrated circuit device includes: forming a first stack of active-region structures that extend in a first direction parallel to a surface of a substrate, the forming the first stack of active-region structures including: forming a lower active-region structure; and forming an upper active-region structure stacked with the lower active-region structure along a third direction perpendicular to the substrate; forming a front-side power rail in an upper conductive layer above both the lower active-region structure and the upper active-region structure; forming a back-side power rail in a lower conductive layer below both the lower active-region structure and the upper active-region structure; and forming a filler cell having therein a segment of the first stack of active-region structures, the forming the filler cell including: forming a power via-connector which extends in the third direction and conductively connects the front-side power rail with the back-side power rail, wherein the filler cell is formed to be free of any dynamic transistor, a dynamic transistor being a transistor configured to have a channel state thereof changing with time.

In some embodiments, the filler cell is formed free of any transistor. In some embodiments, the forming the filler cell includes forming the segment of the first stack of active-region structures to be bounded between a first vertical cell boundary and a second vertical cell boundary of the filler cell, each of the first vertical cell boundary and the second vertical cell boundary extending in a second direction. In some embodiments, the forming the filler cell includes: forming first and second lower isolation regions in the lower active-region structure; and forming first and second upper isolation regions in the upper active-region structure. In some embodiments, the forming the first and second lower isolation regions includes: forming the first lower isolation region at a location in the lower active-region structure that is aligned with the first vertical cell boundary, and forming the second lower isolation region at a location in the lower active-region structure that is aligned with the second vertical cell boundary; and the forming the first and second upper isolation regions includes: forming the first upper isolation region at a location in the upper active-region structure that is aligned with the first vertical cell boundary, and forming the second upper isolation region at a location in the upper active-region structure that is aligned with the second vertical cell boundary.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device comprising:
a first stack of active-region structures extending in a first direction parallel to a surface of a substrate, the first stack of active-region structures including a lower active-region structure and an upper active-region structure stacked with each other on the substrate along a third direction perpendicular to the substrate;
a front-side power rail extending in the first direction in an upper conductive layer above both the lower active-region structure and the upper active-region structure;
a back-side power rail extending in the first direction in a lower conductive layer below both the lower active-region structure and the upper active-region structure;
an array of vertical power lines, wherein each vertical power line in the array of vertical power lines extends in a second direction parallel to the surface of a substrate in a conductive layer which is different from the upper conductive layer and the lower conductive layer, the second direction being perpendicular to the first direction; and
a filler cell having therein a segment of the first stack of active-region structures and having therein a power via-connector which extends in the third direction and conductively connects the front-side power rail with the back-side power rail, and wherein the filler cell is between two of the vertical power lines.

2. The integrated circuit device of claim 1, wherein the segment of the first stack of active-region structures in the filler cell has a width along the second direction smaller than an average width of the first stack of active-region structures.

3. The integrated circuit device of claim 1, wherein either the front-side power rail or the back-side power rail is connected to a vertical power line in the array of vertical power lines with a via-connector passing through a layer of inter layer dielectric.

4. The integrated circuit device of claim 1, wherein the filler cell is free of any transistor.

5. The integrated circuit device of claim 1, wherein the filler cell has one or more transistors therein, and each of the transistors in the filler cell has a channel thereof configured in a static state which remains unchanged over time.

6. The integrated circuit device of claim 5, wherein the filler cell has one or more transistors therein, and each of the transistors in the filler cell has a gate terminal thereof configured either as a floating node or as a voltage node having a constant voltage.

7. The integrated circuit device of claim 1, wherein the filler cell further comprises:
a first vertical cell boundary extending in the second direction and passing through both a first isolation region in the lower active-region structure and a second isolation region in the upper active-region structure at a first end of the segment of the first stack of active-region structures; and
a second vertical cell boundary extending in the second direction and passing through both a third isolation region in the lower active-region structure and a fourth isolation region in the upper active-region structure at a second end of the segment of the first stack of active-region structures.

8. The integrated circuit device of claim 1, further comprising:
a second stack of active-region structures extending in the first direction; and
a third stack of active-region structures extending in the first direction, wherein the first stack of active-region structures extends in the first direction between the second stack of active-region structures and the third stack of active-region structures, and wherein each vertical power line in the array of vertical power lines extends across each of the first stack, the second stack, and the third stack of active-region structures.

9. The integrated circuit device of claim 8, wherein none of the second stack of active-region structures and the third stack of active-region structures passes through the filler cell.

10. The integrated circuit device of claim 8, further comprising:
a logic circuit cell adjacent to the filler cell, the logic circuit cell having therein a segment of the second stack of active-region structures, wherein the filler cell has a vertical cell boundary extending in the second direction along a reference line which is between two vertical cell boundaries of the logic circuit cell.

11. An integrated circuit device comprising:
multiple stacks of active-region structures each extending in a first direction parallel to a surface of a substrate, where the multiple stacks of active-region structures include a first stack of active-region structures extending in the first direction between a second stack of active-region structures and a third stack of active-region structures;
a front-side power rail in an upper conductive layer above the multiple stacks of active-region structures;
a back-side power rail in a lower conductive layer below the multiple stacks of active-region structures;
a filler cell having therein a segment of the first stack of active-region structures and having therein a power via-connector which conductively connects the front-side power rail with the back-side power rail, wherein the power via-connector extends in a third direction perpendicular to the surface of the substrate, and wherein the filler cell is free of any dynamic transistor, a dynamic transistor being a transistor configured to have a channel state thereof changing with time; and
a logic circuit cell adjacent to the filler cell, the logic circuit cell having therein a segment of the second stack of active-region structures, wherein the filler cell has a vertical cell boundary extending in a second direction along a reference line which is between two vertical cell boundaries of the logic circuit cell, the second direction being perpendicular to the first direction.

12. The integrated circuit device of claim 11, wherein the filler cell is free of any transistor.

13. The integrated circuit device of claim 11, wherein each of the second stack of active-region structures and the third stack of active-region structures is adjacent to the first stack of active-region structures, and wherein none of the second stack of active-region structures and the third stack of active-region structures passes through the filler cell.

14. The integrated circuit device of claim 11, wherein the segment of the first stack of active-region structures is bounded between a first vertical cell boundary and a second vertical cell boundary of the filler cell, and wherein each of the first vertical cell boundary and the second vertical cell boundary extends in the second direction and intersects the first stack of active-region structures.

15. The integrated circuit device of claim 11, wherein the filler cell is bounded between a first horizontal cell boundary extending in the first direction and a second horizontal cell boundary extending in the first direction.

16. A method of fabricating an integrated circuit device, the method comprising:
forming a first stack of active-region structures that extend in a first direction parallel to a surface of a substrate, the forming the first stack of active-region structures including:
forming a lower active-region structure; and
forming an upper active-region structure stacked with the lower active-region structure along a third direction perpendicular to the substrate;
forming a front-side power rail in an upper conductive layer above both the lower active-region structure and the upper active-region structure;
forming a back-side power rail in a lower conductive layer below both the lower active-region structure and the upper active-region structure; and
forming a filler cell having therein a segment of the first stack of active-region structures, the forming the filler cell including:
forming a power via-connector which extends in the third direction and conductively connects the front-side power rail with the back-side power rail, wherein the filler cell is formed to be free of any dynamic transistor, a dynamic transistor being a transistor configured to have a channel state thereof changing with time.

17. The method of claim 16, wherein the filler cell is formed free of any transistor.

18. The method of claim 16, wherein the forming the filler cell includes:
forming the segment of the first stack of active-region structures to be bounded between a first vertical cell boundary and a second vertical cell boundary of the filler cell, each of the first vertical cell boundary and the second vertical cell boundary extending in a second direction.

19. The method of claim 18, wherein the forming the filler cell includes:
forming first and second lower isolation regions in the lower active-region structure; and
forming first and second upper isolation regions in the upper active-region structure.

20. The method of claim 19, wherein:
the forming the first and second lower isolation regions includes:
forming the first lower isolation region at a location in the lower active-region structure that is aligned with the first vertical cell boundary, and
forming the second lower isolation region at a location in the lower active-region structure that is aligned with the second vertical cell boundary; and
the forming the first and second upper isolation regions includes:
forming the first upper isolation region at a location in the upper active-region structure that is aligned with the first vertical cell boundary, and
forming the second upper isolation region at a location in the upper active-region structure that is aligned with the second vertical cell boundary.
